(19) United States
(12) Patent Application Publication
(10) Pub. No.: US 2011/0183488 A1
(43) Pub. Date: Jul. 28, 2011

(54) SEMICONDUCTOR DEVICE AND METHOD OF FABRICATING THE SAME

(75) Inventor: Yoshihiro TAKAISHI, Tokyo (JP)

(73) Assignee: ELPIDA MEMORY, INC., Tokyo (JP)

(21) Appl. No.: 13/012,515

(22) Filed: Jan. 24, 2011

(30) Foreign Application Priority Data
Jan. 26, 2010 (JP) 2010-014416

(51) Int. Cl. H01L 21/02; H01L 21/768

(52) U.S. Cl. 438/381; 438/675; 257/E21.577; 257/E21.008

(57) ABSTRACT

A method for forming a semiconductor device includes the following processes. A substrate structure having an insulating upper surface is formed. The insulating upper surface has a step. An insulating layer is formed over the insulating upper surface. The insulating layer covers the step. The insulating layer includes first and second portions which are bounded by the step. The first portion is thinner than the second portion. First and second grooves are formed in the first and second portions, respectively. The first groove is shallower than the second groove. First and second conductive films which fill up the first and second grooves, respectively are formed. The first conductive film is thinner than the second conductive film.

### BACKGROUND OF THE INVENTION

1. Field of the Invention

The present invention relates to a semiconductor device and a method of fabricating the same.

Priority is claimed on Japanese Patent Application No. 2010-014416, Jan. 26, 2010, the content of which is incorporated herein by reference.

2. Description of the Related Art

Low resistance of semiconductor devices is required for a high-speed operation and a low voltage of a device.

In a 4F² dynamic random access memory (DRAM) cell using a three-dimensional (3D) pillar transistor in a memory cell region, it is necessary to raise a local buried bit line constituting a memory cell in the periphery and to connect the local buried bit line to a global bit line. Thus, the global bit line should be arranged at a narrow pitch of 2F on the memory cell, and interconnection capacity between global bit lines should be reduced. To reduce interconnection capacity of the memory cell region, a method of reducing a height of the global bit line is known. On the other hand, for peripheral interconnections of a peripheral circuit region, low resistance is required from the viewpoints of the high-speed operation and the low voltage of the device. It is necessary to make the interconnections thick so as to reduce the resistance of the interconnections of the peripheral circuit region. As a result, the interconnection of the memory cell region should be thin (with a low height), the interconnection of the peripheral circuit region should be thick (with a high height), and it is necessary to simultaneously form the interconnections having different shapes (depths).

A technique of forming interconnections so that the interconnection thickness of the memory cell region is different from that of the peripheral circuit region is disclosed in JP-A-10-223858.

### SUMMARY

In one embodiment, a method for forming a semiconductor device may include, but is not limited to the following processes. A substrate structure having an insulating upper surface is formed. The insulating upper surface has a step. An insulating layer is formed over the insulating upper surface. The insulating layer covers the step. The insulating layer includes first and second portions which are bounded by the step. The first portion is thinner than the second portion. First and second grooves are formed in the first and second portions, respectively. The first groove is shallower than the second groove. First and second conductive films which fill up the first and second grooves, respectively are formed. The first conductive film is thinner than the second conductive film.

In another embodiment, a method for forming a semiconductor device may include, but is not limited to the following processes. A semiconductor substrate is formed. An interlayer insulating film is formed over the semiconductor substrate. A layered structure is selectively formed over the interlayer insulating film. The layered structure has an edge. A first insulating layer is formed over the interlayer insulating film and the layered structure. The insulating layer covers the edge. First and second grooves are formed in the first insulating layer. The first groove is shallower than the second groove. The first groove is positioned over the layered structure. The second groove has a bottom level lower than the top of the layered structure. First and second conductive films which fill up the first and second grooves, respectively are formed. The first conductive film is thinner than the second conductive film.

In still another embodiment, a method for forming a semiconductor device may include, but is not limited to the following processes. A semiconductor substrate having a memory cell region and a peripheral circuit region is formed. An interlayer insulating film is formed over the semiconductor substrate. A capacitor is formed in the interlayer insulating film in the memory cell region. An insulating layer is formed over the capacitor in the memory cell region and the first interlayer insulating film in the peripheral circuit region. First and second grooves are formed in the insulating layer in the memory cell region and the peripheral circuit region, respectively. The first groove is positioned over the capacitor. The first groove is shallower than the second groove. First and second conductive films which fill up the first and second grooves, respectively are formed. The first conductive film is thinner than the second conductive film.

In still another embodiment, a semiconductor device includes, but is not limited to the following elements. A substrate structure having an insulating upper surface is formed, the insulating upper surface having a step. An insulating layer is formed over the insulating upper surface the insulating layer covering the step. The insulating layer includes first and second portions which are bounded by the step. The first portion is thinner than the second portion. First and second grooves are formed in the first and second portions, respectively. The first groove is shallower than the second groove. First and second conductive films are formed. The first and second conductive films fill up the first and second grooves, respectively. The first conductive film is thinner than the second conductive film.

In still another embodiment, a semiconductor device includes, but is not limited to the following elements. A semiconductor substrate is formed. An interlayer insulating film is formed over the semiconductor substrate. A layered structure is selectively formed over the interlayer insulating film. The layered structure has an edge. A first insulating layer is formed over the interlayer insulating film and the layered structure. The insulating layer covers the edge. First and second grooves are formed in the first insulating layer. The first groove is shallower than the second groove. The first groove is positioned over the layered structure. The second groove has a bottom level lower than the top of the layered structure. First and second conductive films which fill up the first and second grooves, respectively are formed. The first conductive film is thinner than the second conductive film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view illustrating a memory cell in accordance with one embodiment of the present invention;

FIG. 2 is a fragmentary cross sectional elevation view, taken along a 1B-1B′ line of FIG. 3, illustrating a memory in accordance with one embodiment of the present invention;

FIG. 3 is a fragmentary cross sectional elevation view, taken along a 1C-1C′ line of FIG. 1, illustrating a memory in accordance with one embodiment of the present invention;

FIG. 4 is a fragmentary cross sectional elevation view illustrating a memory in a step involved in a method of forming the semiconductor device of FIG. 10;

FIG. 5 is a fragmentary cross sectional elevation view illustrating a memory in a step involved in a method of forming the semiconductor device of FIG. 10;

FIG. 6 is a fragmentary cross sectional elevation view illustrating a memory in a step involved in a method of forming the semiconductor device of FIG. 10;

FIG. 7 is a fragmentary cross sectional elevation view illustrating a memory in a step involved in a method of forming the semiconductor device of FIG. 10;

FIG. 8 is a fragmentary cross sectional elevation view illustrating a memory in a step involved in a method of forming the semiconductor device of FIG. 10;

FIG. 9 is a fragmentary cross sectional elevation view illustrating a memory in a step involved in a method of forming the semiconductor device of FIG. 10;

FIG. 10 is a fragmentary cross sectional elevation view, taken along a 8A-8A′ line of FIG. 12, illustrating a memory in accordance with one embodiment of the present invention;

FIG. 11 is a fragmentary cross sectional elevation view, taken along a 8B-8B′ line of FIG. 12, illustrating a memory in accordance with one embodiment of the present invention;

FIG. 12 is a fragmentary plan view integrally illustrating a memory cell including a semiconductor device in accordance with another embodiment of the present invention;

FIG. 13 a fragmentary diagram of constitution of memory cell array of a semiconductor device in accordance with one embodiment of the present invention;

FIG. 14 is a fragmentary cross sectional elevation view illustrating a memory cell including a semiconductor device in accordance with another embodiment of the present invention;

FIG. 15 is a fragmentary cross sectional elevation view illustrating a memory cell including a semiconductor device in accordance with another embodiment of the present invention;

FIG. 16 is a fragmentary cross sectional elevation view illustrating a memory cell including a semiconductor device in accordance with another embodiment of the present invention;

FIG. 17 is a fragmentary cross sectional elevation view illustrating a memory cell including a semiconductor device in accordance with another embodiment of the present invention;

FIG. 18 is a fragmentary cross sectional elevation view illustrating a memory cell including a semiconductor device in accordance with still another embodiment of the present invention;

FIG. 19 is a fragmentary cross sectional elevation view illustrating a memory cell including a semiconductor device in accordance with still another embodiment of the present invention;

FIG. 20 is a fragmentary cross sectional elevation view illustrating a memory cell including a semiconductor device in accordance with still another embodiment of the present invention;

FIG. 21 is a fragmentary cross sectional elevation view illustrating a memory cell including a semiconductor device in accordance with still another embodiment of the present invention;

FIG. 22 is a fragmentary cross sectional elevation view illustrating a memory cell including a semiconductor device in accordance with still another embodiment of the present invention;

FIG. 23 is a fragmentary cross sectional elevation view illustrating a memory cell including a semiconductor device in accordance with still another embodiment of the present invention; and

FIG. 24 is a fragmentary cross sectional elevation view illustrating a memory cell including a semiconductor device in accordance with the related art of the present invention.

### DETAILED DESCRIPTION OF THE PREFERRED EMBODIMENTS

Before describing the present invention, the related art will be explained in order to facilitate the understanding of the present invention.

The technique disclosed in the above-described JP-A-10-223858 is difficult to apply to a semiconductor device having a narrow-pitch structure such as a 4F² DRAM cell using a 3D pillar transistor in a memory cell region. Accordingly, a semiconductor device in which interconnections having different heights are formed in a memory cell region and a peripheral circuit region and a method of manufacturing the same are required in a semiconductor device having a narrow pitch structure such as a 4F² DRAM cell using a 3D pillar transistor. According to this, the interconnection capacity of the memory cell region is reduced. Furthermore, the interconnection resistance of the peripheral circuit region is reduced.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method for forming a semiconductor device may include, but is not limited to the following processes. A substrate structure having an insulating upper surface is formed. The insulating upper surface has a step. An insulating layer is formed over the insulating upper surface. The insulating layer covers the step. The insulating layer includes first and second portions which are bounded by the step. The first portion is thinner than the second portion. First and second grooves are formed in the first and second portions, respectively. The first groove is shallower than the second groove. First and second conductive films which fill up the first and second grooves, respectively are formed. The first conductive film is thinner than the second conductive film.

In some cases, the method may further include, but is not limited to, forming a contact plug in the substrate structure. Forming the second groove may include exposing side and top of the contact plug.

In some cases, forming the second conductive film may include, but is not limited to, forming the second conductive film which covers the side and top of the contact plug.

In some cases, the contact plug may have, but is not limited to, a top which is substantially the same in level as an upper surface of the insulating layer.

In some cases, the method may further include, but is not limited to, forming a contact plug in the substrate structure. Forming the second groove may include exposing a top of the contact plug.

In some cases, the forming the second conductive film may include, but is not limited to, forming the second conductive film which covers the top of the contact plug with a material of the second conductive film.

In some cases, the method may further include, but is not limited to, forming an etching stopper film on the insulating upper surface. Forming the first and second grooves may include carrying out an etching process using the etching stopper film.

In some cases, the top of the contact plug may have, but is not limited to, a top which is substantially the same level as an upper surface of the etching stopper film.

In another embodiment, a method for forming a semiconductor device may include, but is not limited to the following processes. A semiconductor substrate is formed. An interlayer insulating film is formed over the semiconductor substrate. A layered structure is selectively formed over the interlayer insulating film. The layered structure has an edge. A first insulating layer is formed over the interlayer insulating film and the layered structure. The insulating layer covers the edge. First and second grooves are formed in the first insulating layer. The first groove is shallower than the second groove. The first groove is positioned over the layered structure. The second groove has a bottom level lower than the top of the layered structure. First and second conductive films which fill up the first and second grooves, respectively are formed. The first conductive film is thinner than the second conductive film.

In some cases, the method may further include, but is not limited to, forming a contact plug penetrating the interlayer insulating film. Forming the second groove may include exposing side and top of the contact plug.

In some cases, forming the second conductive film may include, but is not limited to, forming the second conductive film which covers the side and top of the contact plug.

In some cases, the contact plug may have, but is not limited to, a top which is substantially the same level as an upper surface of the first insulating layer.

In some cases, the method may further include, but is not limited to, forming a contact plug in the substrate structure. Forming the second groove includes exposing a top of the contact plug.

In some cases, forming the second conductive film may include, but is not limited to, forming the second conductive film which covers the top of the contact plug with a material of the second conductive film.

In some cases, the contact plug have, but is not limited to, a top which is substantially the same level as an upper surface of the interlayer insulating film.

In some cases, forming the second conductive film may include, but is not limited to forming the second conductive film which covers the side and top of the contact plug.

In some cases, the contact plug may have, but is not limited to, a top which is substantially the same level as an upper surface of the first insulating layer.

In some cases, the method may further include, but is not limited to, forming a contact plug in the substrate structure. Forming the second groove may include exposing a top of the contact plug.

In some cases, forming the second conductive film may include, but is not limited to, forming the second conductive film which covers the top of the contact plug with a material of the second conductive film.

In some cases, the contact plug may have, but is not limited to, a top which is substantially the same level as an upper surface of the interlayer insulating film.

In some cases, the method may further include, but is not limited to, forming a third insulating layer on the layered structure. The third insulating layer is aligned to the layered structure.

In some cases, the contact plug may have, but is not limited to, a top which is substantially the same level as an upper surface of the interlayer insulating film.

In some cases, the method may further include, but is not limited to, forming an etching stopper film over the interlayer insulating film and the layered structure. Forming the first and second grooves may include carrying out an etching process using the etching stopper film.

In some cases, the contact plug may further have, but is not limited to, a top which is substantially the same level as an upper surface of the etching stopper film.

In still another embodiment, a method for forming a semiconductor device may include, but is not limited to the following processes. A semiconductor substrate having a memory cell region and a peripheral circuit region is formed. An interlayer insulating film is formed over the semiconductor substrate. A capacitor is formed in the interlayer insulating film in the memory cell region. An insulating layer is formed over the capacitor in the memory cell region and the first interlayer insulating film in the peripheral circuit region. First and second grooves are formed in the insulating layer in the memory cell region and the peripheral circuit region, respectively. The first groove is positioned over the capacitor. The first groove is shallower than the second groove. First and second conductive films which fill up the first and second grooves, respectively are formed. The first conductive film is thinner than the second conductive film.

In still another embodiment, a semiconductor device includes, but is not limited to the following elements. A substrate structure having an insulating upper surface is formed, the insulating upper surface having a step. An insulating layer is formed over the insulating upper surface the insulating layer covering the step. The insulating layer includes first and second portions which are bounded by the step. The first portion is thinner than the second portion. First and second grooves are formed in the first and second portions, respectively. The first groove is shallower than the second groove. First and second conductive films are formed. The first and second conductive films fill up the first and second grooves, respectively. The first conductive film is thinner than the second conductive film.

In some cases, the semiconductor device further includes, but is not limited to, a contact plug in the substrate structure. The second conductive film covers the side and top of the contact plug.

In some cases, the semiconductor device includes, but is not limited to, the contact plug having a top which is substantially the same in level as an upper surface of the insulating layer.

In some cases, the semiconductor device further includes, but is not limited to, a contact plug in the substrate structure. The second conductive film covers the top of the contact plug with a material of the second conductive film.

In still another embodiment, a semiconductor device includes, but is not limited to the following elements. A semiconductor substrate is formed. An interlayer insulating film is formed over the semiconductor substrate. A layered structure is selectively formed over the interlayer insulating film. The layered structure has an edge. A first insulating layer is formed over the interlayer insulating film and the layered structure. The insulating layer covers the edge. First and second grooves are formed in the first insulating layer. The first groove is shallower than the second groove. The first groove is positioned over the layered structure. The second groove has a bottom level lower than the top of the layered structure. First and second conductive films which fill up the first and second grooves, respectively are formed. The first conductive film is thinner than the second conductive film.

In some cases, the semiconductor device further includes, but is not limited to, a contact plug penetrating the interlayer insulating film. The second conductive film covers the side and top of the contact plug.

In some cases, the semiconductor device includes, but is not limited to, the contact plug having a top which is substantially the same level as an upper surface of the first insulating layer.

In some cases, the semiconductor device further includes, but is not limited to, a contact plug in the substrate structure. The second conductive film covers the top of the contact plug with a material of the second conductive film.

In some cases, the semiconductor device includes, but is not limited to, the contact plug has a top which is substantially the same level as an upper surface of the interlayer insulating film.

In some cases, the semiconductor device further includes, but is not limited to, a third insulating layer on the layered structure. The third insulating layer is aligned to the layered structure.

In some cases, the semiconductor device includes, but is not limited to, the contact plug has a top which is substantially the same level as an upper surface of the interlayer insulating film.

Hereinafter, in one embodiment, a DRAM (Dynamic Random Access Memory) as the semiconductor device will be described. In the drawings used for the following description, to facilitate understanding of the embodiments, illustrations are partially enlarged and shown, and the sizes and ratios of constituent elements are not limited to being the same as the actual dimensions. Materials, sizes, and the like exemplified in the following description are just examples, and the invention is not limited thereto and may be appropriately modified within the scope which does not deviate from the embodiments.

### First Embodiment

An example of a semiconductor device according to the first embodiment of the present invention will be described as follows. As a DRAM element is formed, vertical metal oxide semiconductor (MOS) transistors are provided in a memory cell region and planar MOS transistors are provided in a peripheral circuit region.

<Semiconductor Device>

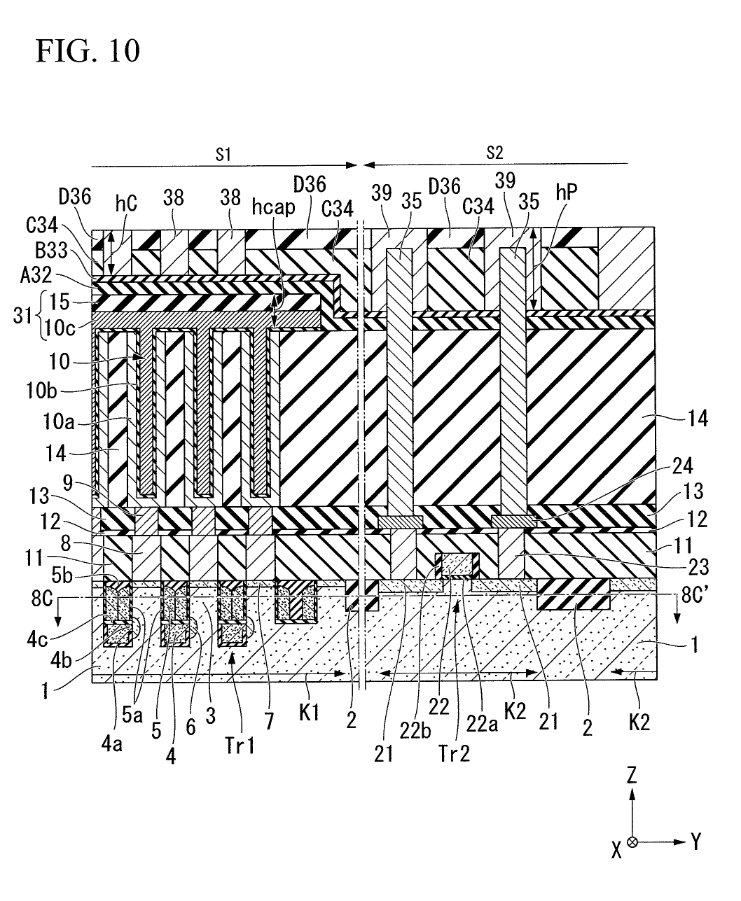

An example of the semiconductor device according to the first embodiment will be described with reference to FIGS. 10 to 13.

A DRAM element related to the semiconductor device of the present embodiment schematically includes a memory cell region and a peripheral circuit region. The peripheral circuit region is arranged adjacent to the memory cell region. The peripheral circuit region includes a sense amplifier circuit, a word line driving circuit, a circuit for input/output from/to the outside, and the like.

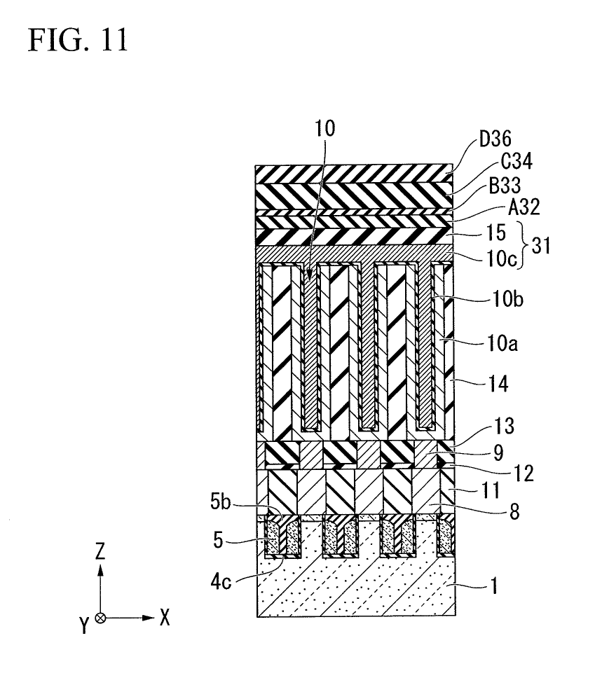

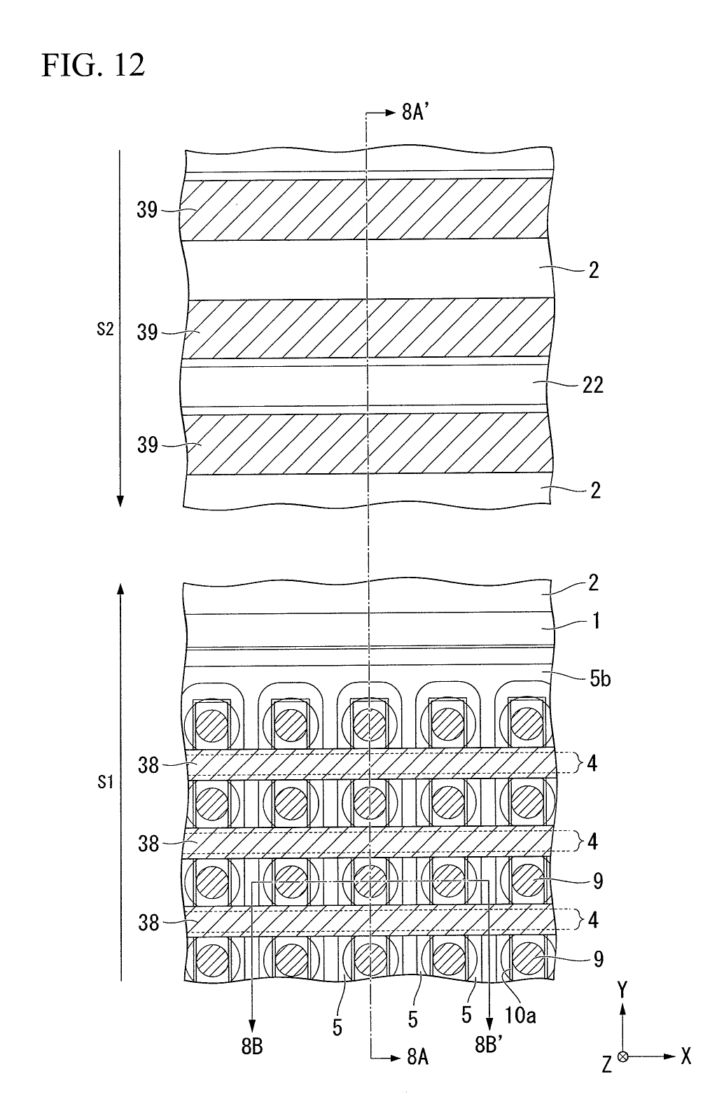

FIG. 12 is a schematic configuration diagram when the semiconductor device of the present embodiment is viewed from the top. In FIG. 12, some components are omitted. FIG. 10 is a schematic cross-sectional view taken along an 8A-8A′ line of FIG. 12, and FIG. 11 is a schematic cross-sectional view taken along an 8B-8B′ line of FIG. 12. These figures are for illustrating the configuration of the semiconductor device, and sizes or dimensions of shown parts are different from those in a dimensional relationship of the actual semiconductor device.

In FIG. 12, a memory cell array, a boundary region of a peripheral circuit region from the memory cell array, and the peripheral circuit region are shown. In the present embodiment as shown in FIG. 12, a direction in which a bit line extends is defined as an X direction, a direction in which a word line extends is defined as a Y direction, and a vertical direction of the semiconductor device is defined as a Z direction. In the following description, the memory cell region may be abbreviated as a cell region S1 and the peripheral circuit region may be abbreviated as a peripheral region S2.

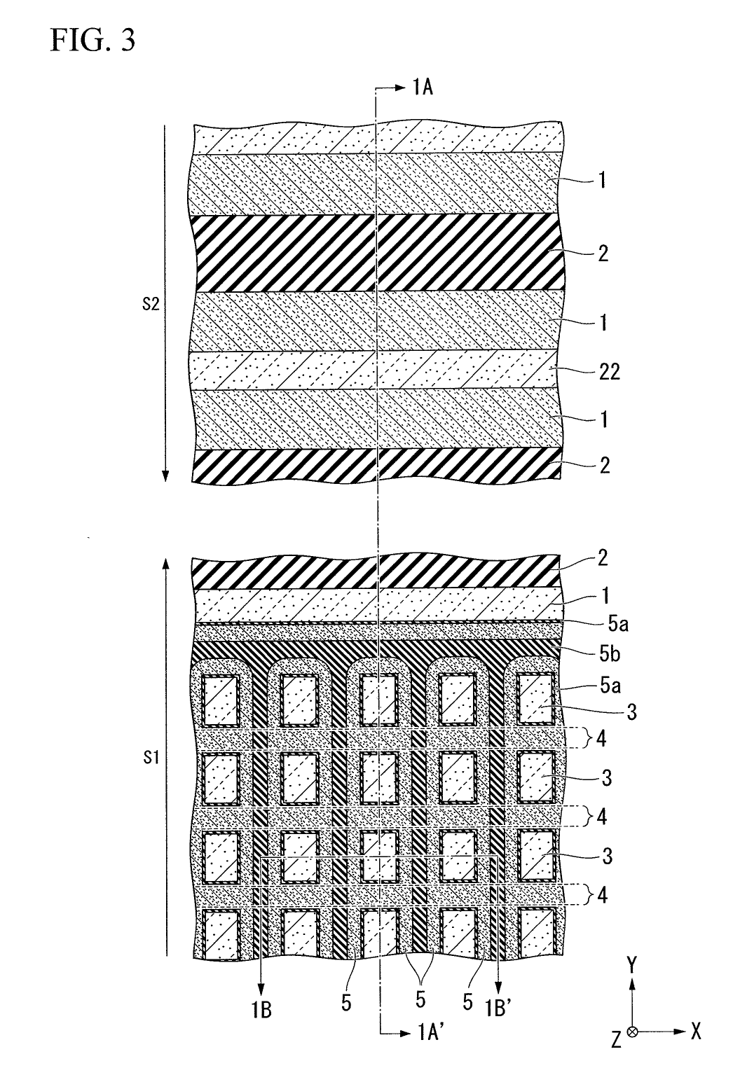

First, the cell region S1 will be described with reference to FIGS. 3 and 10 to 12. As shown in FIG. 10, the cell region S1 may include a cell transistor Tr1, a capacitor element 10, a capacitor upper electrode layer 31, and a cell-region upper interconnection 38. The cell transistor Tr1 may be a vertical MOS transistor for a memory cell. The capacitor element (a capacitive part) 10 may be a deep trench capacitor connected to the cell transistor Tr1 via a cell contact plug 8 and a capacitor contact plug 9. The capacitor upper electrode layer 31 may be formed on the capacitor element 10. The cell-region upper interconnection 38 may be formed over the capacitor upper electrode layer 31 via a fifth interlayer insulating film A32 and a fifth interlayer insulating film B33.

In FIG. 10, a semiconductor substrate includes a semiconductor, for example, silicon containing a predetermined concentration of a first conductivity type impurity, for example, P type impurity. In the semiconductor substrate 1, an isolation region 2 is formed. The isolation region 2 is formed by burying an insulating film such as a silicon oxide (SiO₂) film in a surface of the semiconductor substrate 1 by a shallow trench isolation (STI) method, and thus adjacent cell-region active regions K1 are insulated, isolated, and defined

In the semiconductor substrate 1, a plurality of semiconductor pillars 3 having a columnar shape are vertically formed in a matrix in the cell region S1. As shown in FIG. 3, the semiconductor pillars 3 are defined by word lines 5 and buried bit lines 4, and have a rectangular shape in the plan view. A diffusion region 6 in cell region functioning as one of a source and a drain is formed in a lower portion of the semiconductor pillar 3. A first diffusion layer 7 in the cell region functioning as the other of the source and the drain is formed in an upper portion of the semiconductor pillar 3.

In a lower portion of a trench (hereinafter, referred to as a “first trench”) between the adjacent semiconductor pillars 3 in the Y direction, the buried bit line 4 is formed so that the buried bit line 4 is separated from the semiconductor substrate 1 by a first trench insulating film 4a such as a silicon oxide film or the like. The buried bit line 4 is connected to the first diffusion region 6 via a first trench sidewall contact formed on a sidewall thereof. For example, the buried bit line 4 is formed of an impurity-doped silicon film, which is high in thermal stability and oxidation stability. The buried bit line 4 includes a first trench sidewall contact 4b which is adjacent to a lower portion of the semiconductor pillar 3. The first diffusion region 6 is formed by thermally diffusing an impurity from the buried bit line 4 to lower portions of the semiconductor pillar 3 via the first trench sidewall contact 4b.

The word line 5 is separated from the semiconductor pillar 3 by a first gate insulating film 5a in the cell region. Also, the word line 5 is formed to cover an upper portion of the sidewall of the semiconductor pillar 3. In this embodiment, the word line 5 has a surround gate structure surrounding an outer periphery of a channel region (the semiconductor pillar 3) of the vertical MOS transistor. For example, the first gate insulating film 5a may be formed of silicon nitride or the like.

For example, the word line 5 may be formed of a polysilicon film introduced with an impurity such as phosphorus or arsenic. The material of the word line 5 is not limited to the impurity-doped silicon layer, and a high-melting-point metal film such as a titanium (Ti) film, a titanium nitride (TiN) film, a tantalum (Ta) film, a tantalum nitride (TaN) film, or a tungsten (W) film may be used. A laminate of a high-melting-point metal film and a polysilicon film may be used. A trench-buried insulating film 5b formed of a silicon oxide film is formed in the upper portion of the word line 5 to protect the upper portion of the word line 5.

As shown in FIG. 3, an interval between the adjacent semiconductor pillars 3 is set to be relatively narrow in the Y direction and to be relatively wide in the X direction. Specifically, the interval between the semiconductor pillars 3 adjacent in the Y direction is set to be less than twice a thickness (a width in a horizontal direction) of the word line 5. On the other hand, the interval between the semiconductor silicon pillars 3 adjacent in the X direction is set to be greater than twice a thickness (a width in a horizontal direction) of the word line 5. Thereby, the word lines 5 covering the semiconductor pillars 3 adjacent in a word line direction are in contact with each other. Also, the word lines 5 covering the semiconductor pillars 3 adjacent in a bit line direction are separated from each other. An insulating film 4c includes a silicon oxide film or the like over the buried bit line is formed between the buried bit line 4 formed in a lower portion of the first trench and the word line 5 formed in an upper portion of the first trench, so that the buried bit line 4 and the word line 5 are insulated. The first trench is between the semiconductor pillars 3 adjacent in the Y direction.

A tubular first gate insulating film 5a is provided around the first diffusion layer 7 in the upper portion of the semiconductor pillar 3, so that the word line 5 and the first diffusion layer 7 are insulated. For example, the first diffusion layer 7 is formed by ion-implanting an impurity having a conductivity type opposite to that of the impurity of the semiconductor substrate 1 into a silicon epitaxial layer formed in the upper portion of the semiconductor pillar 3.

By this configuration, a cell transistor is formed in which each of the first diffusion region 6 and the first diffusion layer 7 serves as a source or drain region, the semiconductor pillar 3 serves as a channel region, and a part of the word line 5 serves as a gate.

As shown in FIG. 10, a first interlayer insulating film 11 includes an insulating film such as a silicon oxide film on the semiconductor substrate 1, and the cell contact plug 8 is formed to penetrate the first interlayer insulating film 11. The cell contact plug 8 is formed to be connected to the first diffusion layer 7. For example, the cell contact plug 8 includes a polycrystalline silicon layer containing phosphorus.

A third interlayer insulating film 13 includes an insulating film such as a silicon oxide film above the first interlayer insulating film 11 via a second interlayer insulating film 12. The capacitor contact plug 9 is formed to be connected to the cell contact plug 8 through the second interlayer insulating film 12 and the third interlayer insulating film 13. For example, the capacitor contact plug 9 includes a film in which tungsten (W) is laminated on a barrier film such as TiN/Ti.

A fourth interlayer insulating film 14 may be formed of an insulating film such as a silicon oxide film over the third interlayer insulating film 13, and the capacitor element 10 is formed to be connected to the capacitor contact plug 9.

The capacitor element 10 includes a capacitor lower electrode film 10a, a capacitor upper electrode film 10c, and a high-dielectric capacitor insulating film 10b formed between the two electrode films. As the high dielectric, for example, zirconium oxide (ZrO₂), aluminum oxide (Al₂O₃), hafnium oxide (HfO₂), or a laminate thereof can be used. A high-melting-point metal film such as a TiN film, a Ti film, a W film, or a ruthenium film, an impurity-doped silicon film, a laminate of their materials, or the like can be used in the capacitor lower electrode film 10a and the capacitor upper electrode film 10c. The capacitor lower electrode film 10a is conducted with the capacitor contact plug 9.

A capacitor electrode protection film 15 includes a silicon oxide film is formed over the capacitor element 10 to cover the surface of the capacitor upper electrode film 10c. A capacitor upper electrode layer 31 including the capacitor upper electrode film 10c located above the fourth interlayer insulating layer 14 and the capacitor electrode protection film 15 is formed to cover all of a plurality of memory cells formed in the cell region S1.

To cover the surface and a side surface of the capacitor upper electrode layer 31, a fifth interlayer insulating film A32 and a fifth interlayer insulating film B33, which include silicon oxide films, are sequentially laminated and formed. A fifth interlayer insulating film C34 and a fifth interlayer insulating film D36 are sequentially laminated and formed over the fifth interlayer insulating film B33. As the fifth interlayer insulating film C34, for example, a silicon oxide film may be used, and a boron-phosphorus SiO₂ glass (BPSG) film including phosphorus and boron, a spin on dielectrics (SOD) film (a coating-based insulating film of polysilazane or the like), SiOC, which is a low dielectric constant film, SiOF, or the like may be used. For example, the fifth interlayer insulating film D36 is formed of a silicon oxide film.

A first upper interconnection 38 in the cell region is formed over the fifth interlayer insulating film B33 to penetrate the fifth interlayer insulating film C34 and the fifth interlayer insulating film D36. The first upper interconnection 38 is formed as follows. A copper (Cu) film is formed after a barrier metal film including TiN or the like is formed. Then, a seed film serving as a seed layer is formed of Cu or the like. A metal material constituting the first upper interconnection 38 is not limited to the Cu film, and an aluminum (Al) film or a W film may be used. The first upper interconnection 38 extends in the X direction and is arranged at the same pitch as the buried bit line 4 in the Y direction.

Next, the peripheral region S2 will be described with reference to FIGS. 10 to 12. In the following description, the same components as those of the above-described cell region S1 are denoted by the same reference numerals, and a description thereof is omitted.

As shown in FIG. 10, the peripheral region S2 may include a peripheral transistor Tr2, a lower interconnection 24, and a second upper interconnection 39 in the peripheral region S2. The peripheral transistor Tr2 is a planar MOS transistor for a peripheral circuit. The lower interconnection 24 is connected to the peripheral transistor Tr2 via a first contact plug 23. The second upper interconnection 39 is formed to have a thickness that is greater (a height that is higher) than that of the first upper interconnection 38 in a vertical direction by interposing the second contact plug 35 to the lower interconnection 24.

As shown in FIG. 10, second and third diffusion layers 21 and 21 in the peripheral region each functioning as source and drain diffusion layers are separated and formed in a peripheral-region active region K2 isolated by the element isolation regions 2 in the semiconductor substrate 1. A planar gate electrode 22 in the peripheral region S2 is formed between the second and third diffusion layers 21 and 21. The gate electrode 22 includes the same material as the word line 5 of the above-described cell region S41.

A second gate insulating film 22a in a peripheral region S2 is formed between the gate electrode 22 and the semiconductor substrate 1. As the second gate insulating film 22a, for example, a silicon oxide film may be used and a high-dielectric film (high-K film) containing hafnium (Hf) or the like, a laminate of a silicon nitride film and a silicon oxide film, or the like as well as a single-layer silicon oxide film may be used.

On a sidewall of the gate electrode 22, a gate sidewall film 22b in the peripheral region S2 is formed to include an insulating film of silicon nitride (Si₃N₄) or the like.

The third diffusion layer 21 includes a lightly doped drain (LDD) diffusion layer formed in a lower layer portion thereof and a high-concentration diffusion layer formed on an upper layer portion thereof. The LDD diffusion layer is formed by implanting an impurity having a conductivity type opposite to that of the impurity of the semiconductor substrate 1 in a low dose amount using the gate electrode 22 as a mask. The high-concentration diffusion layer is formed by implanting an impurity having a conductivity type opposite to that of the impurity of the semiconductor substrate 1 with a dose amount of a concentration higher than that of the LDD diffusion layer using the gate electrode 22 and the gate sidewall film 22b as a mask.

The first interlayer insulating film 11 and the second interlayer insulating film 12 are formed over the semiconductor substrate 1, and the lower interconnection 24 formed of Al, Cu, or the like is formed over the second interlayer insulating film 12. The first contact plug 23 is formed to be connected to the third diffusion layer 21 and the lower interconnection 24 through the first interlayer insulating film 11 and the second interlayer insulating film 12. The first contact plug 23 is formed by laminating W on a barrier film formed of TiN/Ti or the like. The lower interconnection 24 is constituted by a laminated film formed of tungsten nitride (WN) and W.

The third interlayer insulating film 13 is formed to cover the lower interconnection 24. The fourth interlayer insulating film 14, the fifth interlayer insulating film A32, and the fifth interlayer insulating film B33 are sequentially laminated and formed over the third interlayer insulating film 13. The second contact plug 35 is formed to be connected to the lower interconnection 24 through the third interlayer insulating film 13, the fourth interlayer insulating film 14, the fifth interlayer insulating film A32, and the fifth interlayer insulating film B33, and to have the surface above that of the fifth interlayer insulating film B33. For example, the second contact plug 35 is formed to include a laminated film of a TiN film and a W film.

The fifth interlayer insulating film D36 is formed over the fifth interlayer insulating film B33 with the fifth interlayer insulating film C34 interposed therebetween. A second upper interconnection 39 is formed on the fifth interlayer insulating film B33 to penetrate the fifth interlayer insulating film C34 and the fifth interlayer insulating film D36. The second upper interconnection 39 is formed as follows. A Cu film is formed after a barrier metal film formed of TiN or the like is formed. A seed film serving as a seed layer is formed of Cu or the like. A metal material constituting the second upper interconnection 39 is not limited to the Cu film, and an Al film or a W film may be used.

In this embodiment as shown in FIG. 10, the surface of the second contact plug 35 is substantially consistent with that of the fifth interlayer insulating film C34. This is derived from a method of manufacturing a semiconductor device according to the present embodiment to be described later.

FIG. 12 is a fragmentary horizontal cross-sectional view taken along a plane (XY plane) parallel to the semiconductor substrate 1 by line 8C-8C′ of FIG. 10. There are shown the buried bit line 4, the capacitor contact plug 9, the capacitor lower electrode film 10a, the capacitor upper electrode layer 31, the first upper interconnection 38, and the second upper interconnection 39. As shown in FIG. 10, the capacitor upper electrode layer 31 is formed to cover the entire cell region S1, and is not formed in the peripheral region S2. Thus, the heights of the surfaces of the fifth interlayer insulating film A32 and the fifth interlayer insulating film B33 of the peripheral region S2 are lower than those of the fifth interlayer insulating film A32 and the fifth interlayer insulating film B33 of the cell region S1. A step formed by the fifth interlayer insulating film A32 and the fifth interlayer insulating film B33 is formed near a boundary between the cell region S1 and the peripheral region S2. By providing the above-described step, the thickness of the first upper interconnection 38 can be thin and the thickness of the second upper interconnection 39 can be thick.

Assuming that the height (thickness) of the capacitor upper electrode layer 31 is represented by “hcap”, the height (thickness) of the first upper interconnection 38 is represented by “hC”, and the height (thickness) of the second upper interconnection 39 is represented by “hP”, these thicknesses satisfy hP−hC≈heap. The sum of the thicknesses of the fifth interlayer insulating film A32 and the fifth interlayer insulating film B33 is substantially uniform between in the cell region S1 and in the peripheral region S2.

The surfaces of the first upper interconnection 38 and the second upper interconnection 39 are exposed as shown in FIGS. 10 to 12. However, the semiconductor device is completed by forming an interlayer insulating film, a contact, an interconnection, a passivation film, and the like on the above-described interconnections, if necessary, in the present embodiment.

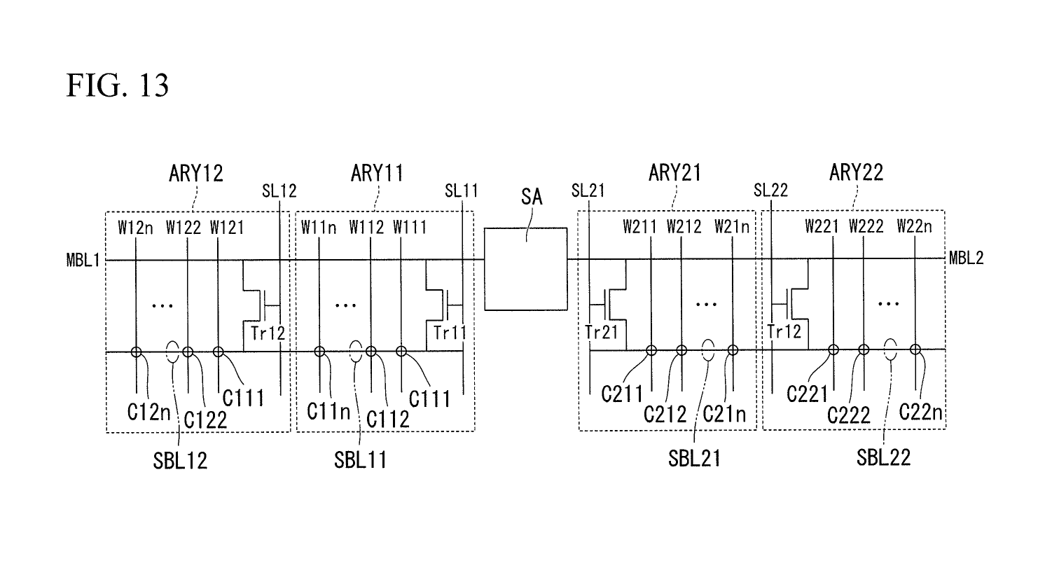

FIG. 13 is a circuit configuration diagram of a memory cell array as an example of the semiconductor device according to the present embodiment. In this example, the memory cell array includes four memory cell array units ARY11, ARY12, ARY21, and ARY22 and a sense amplifier SA. Memory cell array units ARY1j (j=1, 2) are arranged to the left side of the sense amplifier SA, and memory cell array units ARY1i (i=1, 2) are arranged to the right side of the sense amplifier SA.

A main bit line MBL1 is commonly formed in the memory cell array units ARY11 and ARY12, and a main bit line MBL2 is commonly formed in the memory cell array units ARY21 and ARY22.

The main bit MBL1 is connected to a sub-bit line SBL11 via a transistor Tr11, and is connected to a sub-bit line SBL12 via a transistor Tr12. A selection line SL11 is connected to a gate of the transistor Tr11, and a selection line SL12 is connected to a gate of the transistor Tr12. Likewise, in terms of the main bit line MBL2, a transistor Tr21, a transistor Tr22, a selection line SL21, and a selection line SL22 are formed.

The memory cell array units ARYij (i=1, 2 and j=1, 2) have word lines Wij1 to Wijn and sub-bit lines SBLij, and memory cells Cijx are formed at intersections of the word lines Wijx and sub-bit lines SBLij.

When the selection line SL11 is activated, the main bit line MBL1 and the sub-bit line SBL11 are conductive and the memory cell array unit ARY11 is activated. If the word line W11x belonging to the activated memory cell array unit ARY11 is activated, the memory cell C11x is activated and thus the memory cell C11x and the main bit line MBL1 are conductive. The main bit line MBL1 is connected to the sense amplifier SA, and data of the selected memory cell C11x is sensed, amplified, and read by the sense amplifier SA. This configuration is identical even in terms of the selection lines SL12, SL21, and SL22. As described above, the bit lines adopt a hierarchical structure in which the main bit lines MBLi (i=1, 2) are directly connected to the sense amplifier SA and the sub-bit lines SBLij to which the memory cells Cijx are directly connected are connected to the main bit lines MBLi. Accordingly, this structure is referred to as a hierarchical bit line structure. In the hierarchical bit line structure, a configuration in which one sub-bit line is formed for one main bit line is taken.

When data of a memory cell is read and written in the hierarchical bit lines, a selection line of a sub-bit line to which the memory cell belongs is selected, the sub-bit line is connected to the main bit line, and the memory cell belonging to the sub-bit line is connected to the main bit line. Since the memory cell connected to the main bit line can be limited to the memory cell connected to the sub-bit line when the data of the memory cell is read and written as described above, the number of memory cells connected to the main bit line can be reduced if the number of memory cells belonging to the sub-bit line is set to be small.

In the hierarchical bit line structure of this embodiment, the sub-bit line SBLij may be formed of the buried bit line 4 and the main bit line MBLi may be formed of the first upper interconnection 38.

The buried bit line 4 of this embodiment has a structure surrounded by the semiconductor substrate 1 via an insulating film (a first trench insulating film 4a) of which a bottom surface and a side surface are thin. The interconnection capacity per unit length is large. No conductor is formed in proximity to the periphery. The first upper interconnection 38 has the interconnection capacity which is small compared to that of the buried bit line 4.

The sensitivity of sensing memory cell data in the sense amplifier is degraded when the interconnection capacity of the bit line connected to the sense amplifier is large. Read performances of a memory cell are degraded. In this embodiment, it is possible to suppress the degradation of the read performances of a memory cell by the following configurations. A hierarchical bit line configuration is taken so that the sub-bit line is configured by the buried bit line 4 and the main bit line is configured by the first upper interconnection 38. The length of the sub-bit line is set to an appropriate length (that is, appropriately setting the number of memory cells connected to the sub-bit line). During a read operation, the interconnection capacity of the buried bit line added to the main bit line is decreased.

From a point of view that heat treatment resistance and oxidation resistance are excellent, the buried bit line 4 of this embodiment uses an impurity-doped silicon material. Such an impurity-doped silicon film has high interconnection resistance. On the other hand, since the first upper interconnection 38 is formed by a final process, a low-temperature process can be used and thus a Cu interconnection having small interconnection resistance can be used. The bit line has an interconnection delay which is increased to affect the read speed and the write speed when the interconnection resistance is high. In this embodiment, it is possible to suppress the drop of speed of data access to a memory cell by the following configuration. A hierarchical bit line configuration is taken such that the sub-bit line is formed of the buried bit line 4 and the main bit line is formed of the first upper interconnection 38. The length of the sub-bit line is set to an appropriate length (that is, appropriately setting the number of memory cells connected to the sub-bit line). The interconnection resistance of the bit line during read and write operations is decreased.

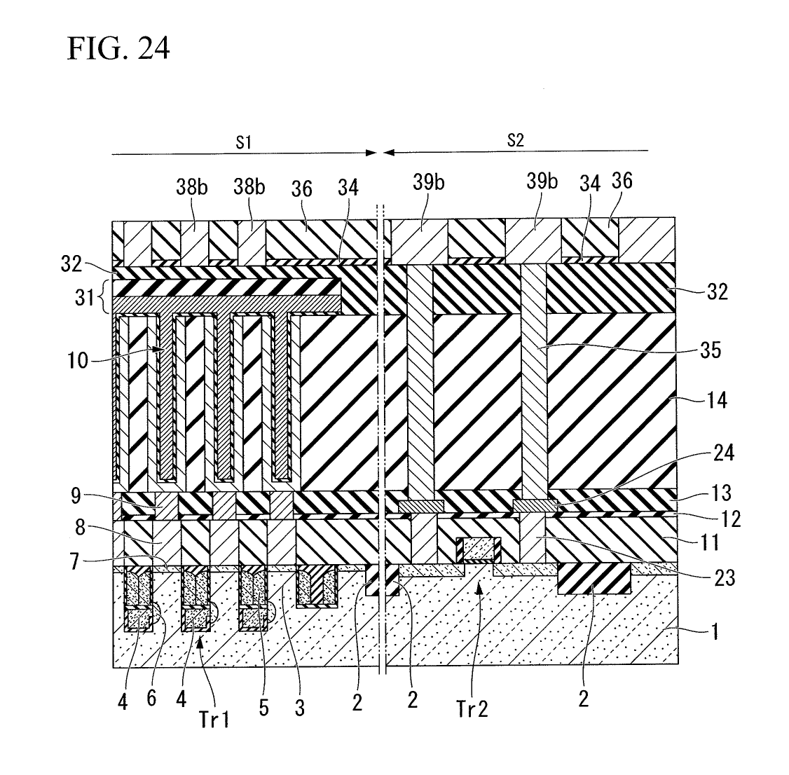

FIG. 24 is a cross-sectional view showing an example of a semiconductor device when the upper interconnection is formed in the cell region S1 and the peripheral region S2 by the related art. Since the same components of FIG. 24 as those of the semiconductor device of this embodiment shown in FIG. 10 are denoted by the same reference numerals, descriptions thereof are omitted. As shown in FIG. 24, a first upper interconnection 38b and a second upper interconnection 39b having the same height (thickness) are formed in the semiconductor device of the related art. However, it is necessary to increase the height of the second upper interconnection 39b so as to improve the reliability of an interconnection through which a high current flows. On the other hand, the height of the second upper interconnection 39b may not be increased since the height of the second upper interconnection 39b is limited by the first upper interconnection 38b. In this case, a countermeasure is taken by increasing the width of the second upper interconnection 39b in the semiconductor device of the related art. As a result, there is a problem in that a chip size may be enlarged.

In the semiconductor device of the present embodiment, it is possible to form a high-density interconnection in the cell region S1 and to form an interconnection through which a high current can flow in the peripheral region S2 by the following configuration. A structure is taken such that the first upper interconnection 38 having a low height (a thin thickness in the vertical direction) is formed in the cell region S1 and the second upper interconnection 39 having a high height (a thick thickness in the vertical direction) is formed in the peripheral region S2. Accordingly, the interconnection capacity of the memory cell region S1 can be reduced and the interconnection resistance of the peripheral circuit region can be reduced.

<Method of Manufacturing Semiconductor Device>

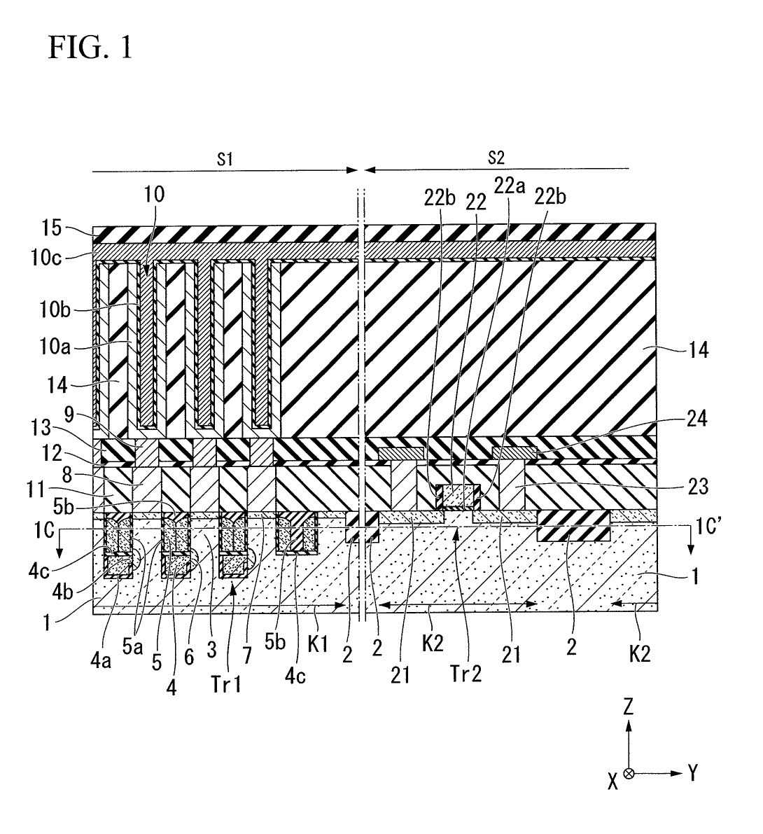

Next, a method of manufacturing the semiconductor device of this embodiment will be described with reference to FIGS. 1 to 12.

The method of manufacturing the semiconductor device of this embodiment schematically includes the following processes. A process (a first process) includes the following forming processes. A cell transistor Tr1 which is a vertical MOS transistor is formed in a memory cell region (a cell region) S1. A peripheral transistor Tr2 which is a planar MOS transistor is formed in a peripheral circuit region (a peripheral region) S2. A deep trench capacitor element 10 is formed over the cell transistor Tr1 of the cell region S1. A process (a second process) of forming a capacitor upper electrode layer 31 over the capacitor element 10 so as to cover the entire cell region S1 is performed. A process (a third process) of forming a second contact plug 35 in the peripheral region S2 is performed. A process (a fourth process) of forming a first upper interconnection 38 and a second upper interconnection 39 is performed. Hereinafter, the processes will be described in detail. The drawings to be referred to for the following description are those illustrating the method of manufacturing the semiconductor device of this embodiment, and dimensions such as sizes and thicknesses of the shown parts/portions are different from those in a dimensional relationship of the actual semiconductor device.

[First Process]

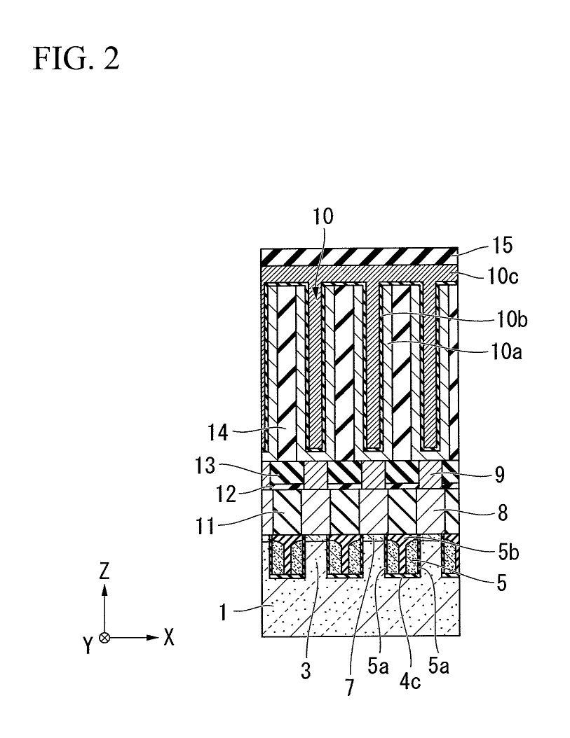

FIGS. 1 to 3 are cross-sectional views in a step in which the first process is terminated. FIG. 1 is a cross-sectional view, taken along an A-A′ line of FIG. 3, showing the method of manufacturing the semiconductor device according to this embodiment. FIG. 2 is a cross-sectional view of line 1B-1B′ of FIG. 3. FIG. 3 is a cross-sectional view in which a buried bit line is overlapped and shown in a cross-sectional view of line 1C-1C′ of FIG. 1.

First, a silicon substrate 1 including silicon is prepared by introducing a predetermined concentration of a first conductivity type (for example, P type) impurity to have the first conductivity type. By a thermal oxidation method, an insulating film such as a silicon oxide film (SiO₂) or the like is buried in the semiconductor substrate 1 in an STI method or the like, and an isolation region 2 is formed. A peripheral-region active region K2 isolated by the isolation region 2 is formed in the peripheral-region S2. A cell-region active region K1 isolated by the isolation region 2 is formed in the cell region S1.

Next, a cell transistor Tr1, which is a vertical MOS transistor, is formed in the cell region S1. The method of manufacturing the cell transistor Tr1 of the configuration of this embodiment may use the same method as previously disclosed in JP-A-2009-10366 by the inventor of the present invention. Accordingly, detailed descriptions of the method of manufacturing the cell transistor Tr1 are omitted and the processes will be described hereinafter.

(Process of Forming Cell Transistor Tr1)

First, first trenches extending in the X direction are formed by etching the semiconductor substrate 1 of the cell-region active region K1 using a first trench opening mask having an opening portion extending in the X direction. Band-shaped semiconductor pillars 3 extending in the X direction are formed to be interposed between the first trenches. The first trenches are trenches between the semiconductor pillars 3 adjacent in a Y direction.

Next, a buried bit line 4 is formed to include an impurity-doped silicon film having excellent heat treatment resistance and oxidation resistance on a first-trench bottom surface via a first insulating film 4a. The first insulating film 4a is removed in a part of a first-trench side portion, and the part becomes a first trench sidewall contact 4b. The buried bit line 4 is in contact with the semiconductor substrate 1 of the sidewall of the semiconductor pillar 3 via the first trench sidewall contact 4b. By performing a heat treatment in this state, impurities of the buried bit line 4 are diffused to the sidewall of the semiconductor pillar 3 contacting via the first trench sidewall contact 4b, and the first diffusion region 6 is formed.

Subsequently, a second trench extending in the Y direction is formed by etching the semiconductor substrate 1 using a second trench opening mask having an opening portion extending in the Y direction. The semiconductor pillars 3 are defined by the combinations of the first and second trenches. The semiconductor pillars 3 are positioned above the buried bit line 4. The second trench is a trench defined between two adjacent pillars of the semiconductor pillars 3, which are aligned in the X direction. The semiconductor pillars 3 are defined by the first and second trenches, and are formed to have a rectangular shape in the plan view. The depth of the second trench is smaller than that of the first trench. The buried bit line 4 is formed within the semiconductor substrate 1 between the semiconductor pillars 3 adjacent to each other in the Y direction. Here, the width of the first trench is greater than that of the second trench.

Next, an insulating film 4c disposed on the buried bit line is formed on the buried bit line 4 and the semiconductor substrate of a bottom portion of the second trench. It is ensured thereby that the buried bit line 4 and a word line 5 will be formed in a subsequent process and that the buried bit line 4 and a word line 5 will be separated from each other.

A first gate insulating film 5a is formed on the exposed sidewall of the semiconductor pillar 3. A cell-region gate electrode film is formed by covering the sidewall and the surface of the semiconductor pillar 3. The cell-region gate electrode film is formed with a thickness so that the inside of the first trench between the semiconductor pillars adjacent in the Y direction is buried and the inside of the second trench between the semiconductor pillars adjacent in the X direction is not buried.

Next, sidewalls formed of the cell-region gate electrode film on sidewalls of two parallel surfaces extending in the Y direction among 4 side surfaces of the semiconductor pillar 3 are formed by etching back the cell-region gate electrode film. Also, the surface of the insulating film 4c disposed on the buried bit line is exposed by separating sidewalls adjacent in the X direction. As shown in FIG. 3, the inside of the semiconductor pillars 3 adjacent in the Y direction is buried by the cell-region gate electrode film. An interconnection is formed by covering the sidewalls of each semiconductor pillar 3 in the Y direction. The interconnection is formed of the cell-region gate electrode film extending in the Y direction. The interconnection functions as the word line 5.

Subsequently, after a trench-buried insulating film 5b is formed to cover the side surface and the surface of the word line, a first diffusion layer 7 is formed in an upper portion of the semiconductor pillar 3.

By forming this configuration, the cell transistor Tr1 is formed in which each of the first diffusion region 6 and the first diffusion layer 7 serves as the source or drain diffusion layer and the word line 5 serves as a gate. The buried bit line 4 is connected beneath the first diffusion region 6.

(Process of Forming Peripheral Transistor Tr2)

A gate electrode 22 in the peripheral region S2 is formed over the semiconductor substrate 1 of the peripheral-region active region K2 with a second gate insulating film 22a interposed therebetween.

The second gate insulating film 22a is formed by a thermal oxidation method to form silicon oxide by oxidizing a surface of the semiconductor substrate 1. As the second gate insulating film 22a, a laminated film of a silicon nitride film and a silicon oxide film or a high-dielectric film (a high-K film) such as a silicon nitride film or a hafnium oxide film may be used.

For example, the gate electrode 22 is formed to include a polysilicon film introduced with an impurity having a conductivity type (for example, such as phosphorus or arsenic in an N type) opposite to that of impurity of the semiconductor substrate 1. The gate electrode 22 may be formed to include a high-melting-point metal film such as a Ti film, a TiN film, a Ta film, or a W film and may be formed by laminating a polysilicon film and a high-melting-point metal film.

Next, an LDD impurity layer is formed around the surface of the semiconductor substrate 1 of both sides of the gate electrode 22. An impurity having a conductivity type opposite to that of the impurities of the semiconductor substrate 1 is implanted in a low dose amount using the gate electrode 22 as a mask. Subsequently, a silicon nitride film is formed to cover the gate electrode 22 by a low-pressure chemical vapor deposition (LP-CVD) method (a reduced pressure chemical vapor deposition (CVD) method). A gate sidewall 22b is formed on a sidewall of the gate electrode 22 by etching back the silicon nitride film. Thereafter, the impurities having a conductivity type opposite to that of the impurity of the semiconductor substrate 1 are implanted in a dose amount of a concentration, which is higher than that of the LDD diffusion layer, using the gate electrode 22 and the gate sidewall film 22b as a mask. Thus, a high-concentration diffusion layer is formed in an upper portion within an LDD impurity layer at both sides of the gate electrode 22. A third diffusion layer 21 is formed of the LDD impurity layer and the high-concentration diffusion layer.

(Process of Forming Contact Plug 8 and Lower Interconnection 24)

After an oxide silicon film is formed over the cell transistor Tr1 and the peripheral transistor Tr2 formed as described above by a CVD method. A first interlayer insulating film 11 is formed by planarizing concave/convex portions of a surface by chemical mechanical polishing (CMP). Thereafter, a contact hole is formed in the cell region S1 by a general method, and the surface of the first diffusion layer 7 of the cell region S1 is partially exposed. Next, a cell contact plug 8 is formed to fill the contact hole. The cell contact plug 8 is formed by polishing until the surface of the first interlayer insulating film 11 is exposed by a CMP method after a polycrystalline silicon film into which impurities are introduced is formed over the entire surface.

Next, for example, a second interlayer insulating film 12 formed of silicon oxide is formed to cover the first interlayer insulating film 11 and the cell contact plug 8 by an LP-CVD method. Thereafter, using the same formation method as that of the above-described cell contact plug, a first contact plug 23 is formed to be connected to the third diffusion layer 21 in the peripheral region S2 and to penetrate the first interlayer insulating film 11 and the second interlayer insulating film 12.

Subsequently, a deposited film formed to include tungsten nitride (WN) and W is deposited and then patterned, thereby forming a lower interconnection 24 in the peripheral region S2 over the first contact plug 23 of the peripheral region S2. Thereafter, a third interlayer insulating film 13 is formed to include silicon oxide or the like to cover the second interlayer insulating film 12 and the lower interconnection 24. Next, a capacitor contact plug 9 is formed to penetrate the second interlayer insulating film 12 and the third interlayer insulating film 13 in the cell region S1 and to be connected to the cell contact plug 8. The capacitor contact plug 9 can be formed by filling an opening with a film in which W is deposited over a barrier film such as TiN/Ti.

(Process of Forming Capacitor Element 10)

A fourth interlayer insulating film 14 is formed to include silicon oxide or the like to cover the third interlayer insulating film 13 and the capacitor contact plug 9. Thereafter, in the cell region S1, a capacitor hole is formed to penetrate the fourth interlayer insulating film 14 and to expose the surface of the capacitor contact plug 9 by a general method. Next, a capacitor lower electrode film 10a is formed to include TiN or the like to cover the side surface and the bottom surface of the capacitor hole. Subsequently, a capacitor insulating film 10b is formed over the capacitor lower electrode film 10a. The capacitor insulating film 10b may be formed to include a high-dielectric insulating film of hafnium oxide, zirconium oxide, aluminum oxide, or the like. Here, as shown in FIG. 1, the capacitor insulating film 10b may be formed in both the cell region S1 and the peripheral region S2.

Next, a capacitor upper electrode film 10c is formed over the capacitor insulating film 10b of the cell region S1 and the peripheral region S2 by a general film formation method. As the capacitor insulating film 10b, a high-melting-point metal film such as a TiN film, a Ti film, a W film, or a ruthenium film, an impurity-doped silicon film, or a laminate of their materials may be used.

By this second process, a capacitor element 10 having a configuration in which the capacitor insulating film 10b is interposed between the capacitor lower electrode film 10a and the capacitor upper electrode 10c can be formed.

[Second Process] (Process of Forming Capacitor Electrode Protection Film 15)

For example, the capacitor electrode protection film 15 is formed by forming a silicon oxide film over capacitor upper electrode film 10c using an LP-CVD method.

(Process of Forming Capacitor Upper Electrode Layer 31)

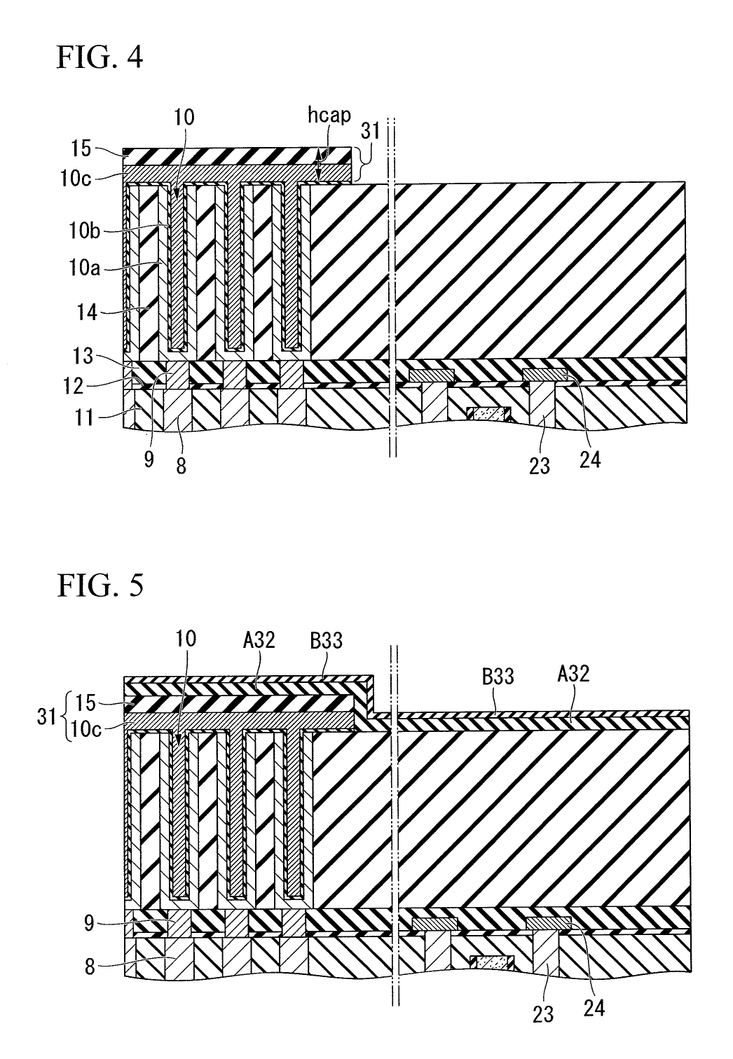

As shown in FIG. 4, the capacitor upper electrode layer 31 is formed as follows. A photoresist pattern is formed to cover the entire cell region S1 using a lithography method. The capacitor upper electrode protection film 15 and the capacitor upper electrode film 10c are sequentially dry-etched using the photoresist pattern as a mask. A hard mask of amorphous carbon or the like to be formed under the photoresist may be used along with the mask. The capacitor upper electrode layer 31 is formed of the capacitor upper electrode 10c and the capacitor upper electrode film 15 located above the surface of the fourth interlayer insulating film 14. In this embodiment, the etching of the fourth process may be performed to dig the fourth interlayer insulating film 14 by etching the capacitor insulating film 10b and the fourth interlayer insulating film 14.

As shown in FIG. 10, a pattern of the capacitor upper electrode layer 31 is formed to cover the capacitor lower electrode film 10a with a margin of a certain extent. That is, the capacitor upper electrode layer 31 is formed in a plate pattern having a flat surface, which covers a plurality of memory cells formed in the cell region S1.

In this embodiment, since the capacitor element 10 formed in the cell region S1 is a deep trench capacitor configured in a 3D structure using a deep hole, and the cell region S1 is in a state in which the deep trench capacitor is closely crowded, the capacitor upper electrode layer 31 can be formed in a plate pattern. Since the capacitor upper electrode layer 31 is formed in the plate pattern having a flat surface, which covers the entire memory cells, the step or level-difference is formed by a laminate of the capacitor upper electrode film 10c and the capacitor upper electrode protection film 15. The step or level-difference is positioned near the boundary between the cell region S1 and the peripheral region S2. In the present embodiment, the step or level-difference causes that upper interconnections will be formed in the cell region S1 and the peripheral region S2 provided that the upper interconnections are different in height from each other as described later.

[Third Process] (Process of Forming Fifth Interlayer Insulating Films A32, B33, and C34)

As shown in FIG. 5, a fifth interlayer insulating film A32 and a fifth interlayer insulating film B33 are formed to include silicon oxide or the like by a CVD method or the like to cover the capacitor upper electrode layer 31 and the fourth interlayer insulating film 14 of the cell region S1 and the peripheral region S2.

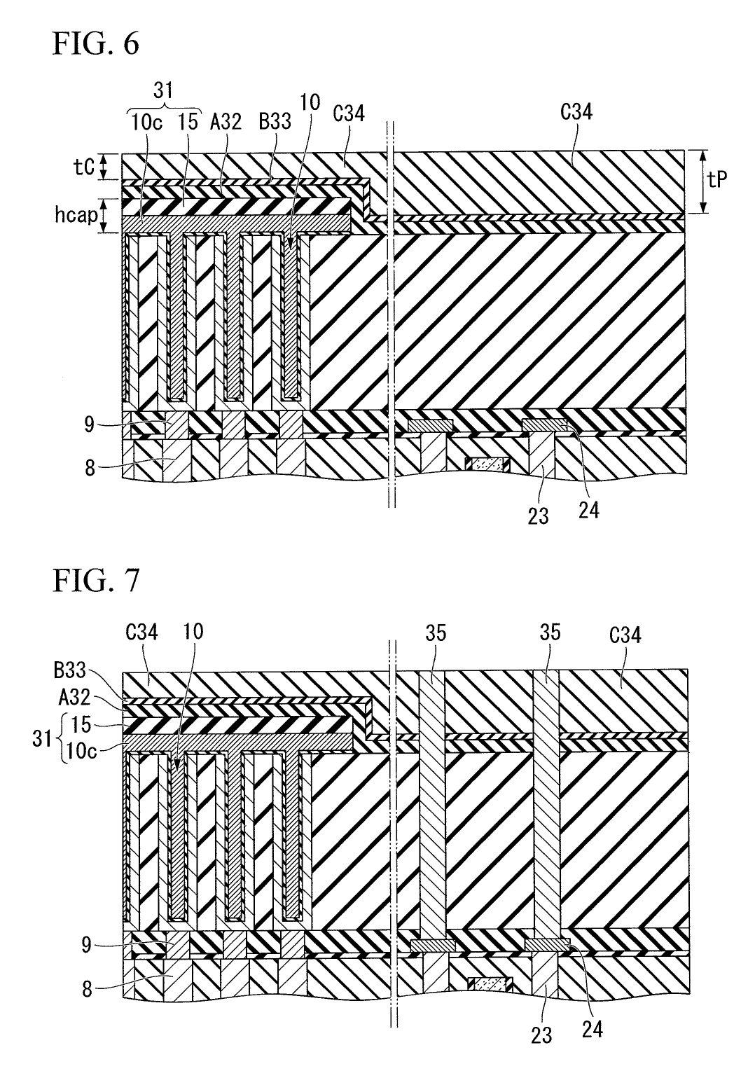

Next, a fifth interlayer insulating film C34 is formed by forming a silicon oxide film using a CVD method or the like to cover the fifth interlayer insulating film B33 (FIG. 6). A BPSG film including phosphorus and boron, an SOD film of a coating film, a SiOC film, which is a low-dielectric-constant film, a SiOF film, or the like may be used as the fifth interlayer insulating film C34.

Thereafter, the fifth interlayer insulating film C34 is polished and planarized using a CMP method. If the SOD film is used, or if the surface is sufficiently flat, it is not necessary to perform the CMP processing. In this embodiment, planarization is performed so that a position of the surface of the fifth interlayer insulating film C34 is globally flat from the capacitor upper electrode layer 31 to the other region.

Here, the thickness of the capacitor upper electrode layer 31 is denoted by hcap, the thickness of the fifth interlayer insulating film C34 on the capacitor upper electrode layer 31 is denoted by tC, and the thickness of a region having no capacitor upper electrode layer 31, that is, the fifth interlayer insulating film C34 in the peripheral region S2, is denoted by tP. In this embodiment, since the thicknesses of the fifth interlayer insulating film A32 and the fifth interlayer insulating film B33 are substantially identical in the cell region S1 and the peripheral region S2, tP-tC is substantially the same as hcap.

(Process of Forming Second Contact Plug)

In the peripheral region S2, a second contact hole reaching from the surface of the fifth interlayer insulating film C34 to the lower interconnection 24 is made by a known method. Next, a second contact filling material fills the second contact hole, thereby forming a laminated film of a TiN film and a W film inside of the second contact hole and covering the fifth interlayer insulating film C34. Subsequently, a second contact plug 35 is formed by polishing and removing the second contact filling material using a CMP method until the surface of the fifth interlayer insulating film C34 is exposed and burying the second contact filling material in the second contact hole (FIG. 7).

“Fourth Process” (Process of Forming First Upper Interconnection 38 and Second Upper Interconnection 39)

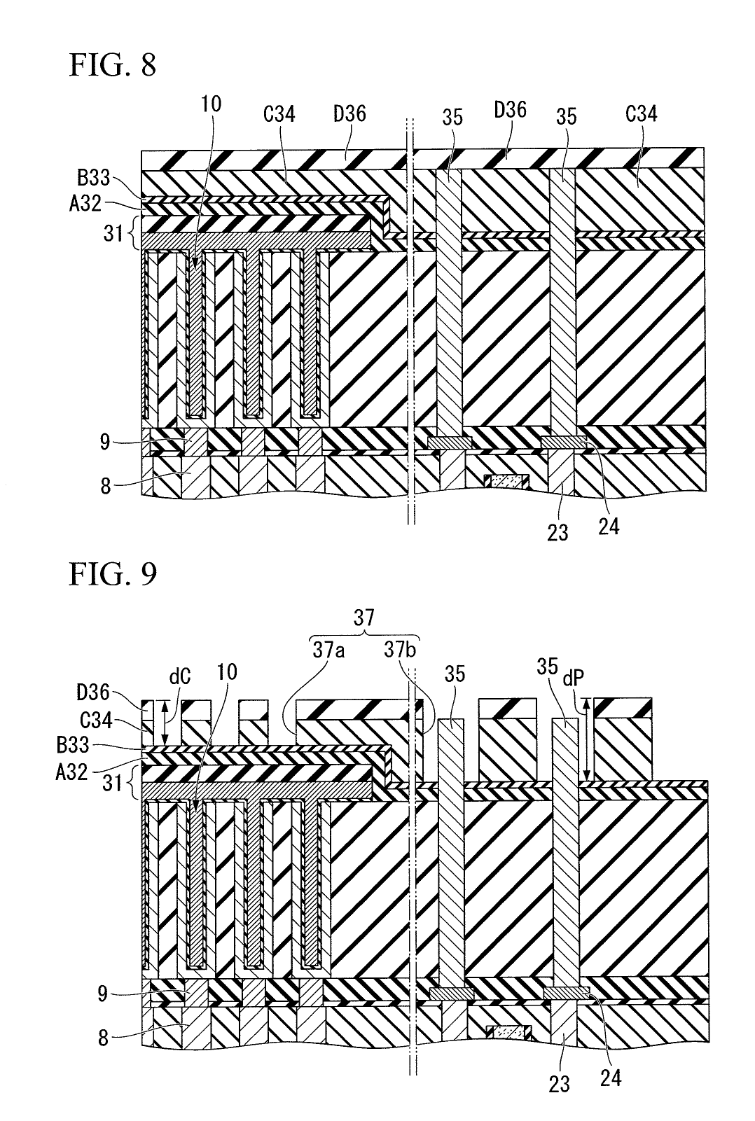

A fifth interlayer insulating film D36 is formed to include a silicon oxide to cover the surface of the fifth interlayer insulating film C34 and the surface of the second contact plug 35 (FIG. 8).

Next, a first interconnection trench 37a in the cell region S1 and a second upper interconnection trench 37b (hereinafter, collectively referred to as an “upper interconnection trench 37”) are formed (FIG. 9). In this etching process, the fifth interlayer insulating film D36 and the fifth interlayer insulating film C34 is sequentially etched. The fifth interlayer insulating film B33 is used as an etching stopper film. An upper interconnection trench mask in which a portion of the first upper interconnection 38 and the second upper interconnection 39 are opened is used. Here, the upper interconnection trench mask corresponds to patterns of the upper interconnections (the first upper interconnection 38 and the second upper interconnection 39) as shown in FIG. 12. A plurality of patterns of first upper interconnection trenches 37a in the cell region S1 extend in the X direction and are arranged at the same pitch as the buried bit line 4 in the Y direction.

In etching process by which the first upper interconnection trench 37 is formed, a condition that an etching rate for the fifth interlayer film B33 is slower than those for the fifth interlayer insulating film C34 and the fifth interlayer insulating film D36 is used. Under this condition, for example, etching process can be performed using gas including fluorocarbon-based gas such as C₄F₈-based gas. In the etching process of this condition, since selectivity is taken even for the second contact plug 35, the second contact plug 35 formed within the second upper interconnection trench 37b remains without being etched. The columnar second contact plug 35 is formed to have the surface and the side surface partially exposed within the second upper interconnection trench 37b. The surface of the second contact plug 35 is substantially consistent with that of the fifth interlayer insulating film C34.

The first upper interconnection trenches 37a are provided in one-to-one correspondence with the buried bit lines 4. From a demand for high integration of memory cells, the buried bit lines are designed to have a width and an interval using dimensions close to the minimum processing size of a photolithographic technique. The buried bit lines are formed in a line and space pattern (hereinafter, referred to as an L/S pattern). Thus, the first upper interconnection 38 to be provided in a process to be described later within the cell-region upper interconnection trench 37a is also formed in the L/S pattern shape using dimensions close to the minimum processing size of the photolithographic technique. On the other hand, since the second upper interconnection 39 to be provided in a process to described later within the second upper interconnection trench 37b is difficult to design in a periodic pattern, an exposure margin is less secured than in the cell region S1, and a pattern width and interval have large dimensions compared to the cell region S1. The width of the Y direction of the second upper interconnection 39 to be formed in a process to be described later is greater than that of the first upper interconnection 38.

Here, if the depths of the cell-region upper interconnection trench 37a and the second upper interconnection trench 37b are respectively denoted by dC and dP, dP−dC≈hcap.

Next, within the upper interconnection trench 37 and on the surface of the fifth interlayer insulating film D36, an underlying layer is formed to include Cu or the like by the following processes. A TiN film as a barrier metal and a seed film serving as a seed layer are formed by a sputtering method. Then, a Cu film is formed thereon using a plating method. A Cu interconnection is used here, but a metal interconnection or the like using an Al film or a W film may be used. Thereafter, by polishing and removing the Cu film and the underlying layer using a CMP method, the surface of the fifth interlayer insulating film D36 is exposed and also the underlying layer and the Cu film are buried in the upper interconnection trench 37. The first upper interconnection 38 including the underlying layer and the Cu film is formed within the cell-region upper interconnection trench 37a. Also, the second upper interconnection 39 including the underlying layer and the Cu film is formed within the second upper interconnection trench 37b (FIG. 10). In the second upper interconnection trench 37b in which the second contact plug 35 is formed, the second upper interconnection 39 is connected to the second contact plug 35.

Here, if the heights of the first upper interconnection 38 and the second upper interconnection 39 are respectively denoted by hC and hP, hC and hP are respectively substantially identical with dC and dP, and hP-hC hcap. A position of the surface of the first upper interconnection 38 is substantially consistent with that of the second upper interconnection 39.

Thereby, the first upper interconnection 38 having a low height can be formed in the cell region S1, and also the second upper interconnection 39 can be formed to have a height greater than that of the first upper interconnection 38, in the peripheral region S2.

After the above-described process, a DRAM element as a semiconductor device is completed by forming an interlayer insulting film, a contact, an interconnection, and a passivation film, if necessary.

The width of the first upper interconnection 38 is close to the minimum processing size as described above. Therefore, it is difficult to secure the step coverage (the coating film state of a step portion of the cell-region upper interconnection trench 37a) of the barrier layer (barrier metal) and the seed layer within the cell-region upper interconnection trench 37a when the first upper interconnection 38 is formed. Hence, an interconnection height is limited. The width of the second upper interconnection 39 in the Y direction is greater than that of the first upper interconnection 38 in the Y direction. Thus, when the second upper interconnection 39 is formed, the step coverage of the barrier layer and the seed layer directed to the cell-region upper interconnection trench 37b is easily secured compared to that of the cell region S1. Accordingly, the height of the second upper interconnection 39 is limited by that of the first upper interconnection 38.

According to the method of manufacturing the semiconductor device of the present embodiment, the first upper interconnection 38 having a low height (a small thickness in the vertical direction) can be formed in the memory cell region (the cell region) S1. Also, the second upper interconnection 39 having a high height (a large thickness in the vertical direction) can be formed in the peripheral circuit region (the peripheral region) S2. Therefore, a high-density interconnection can be formed in the cell region S1 and an interconnection through which high current flows can be formed in the peripheral region S2. The thickness of the first upper interconnection 38 and the thickness of the second upper interconnection 39 can be controlled by adjusting the thickness of the capacitor electrode protection film 15, the thickness of the fifth interlayer insulating film C34, the thickness of the fifth interlayer insulating film D36.

In the method of manufacturing the semiconductor device of the present embodiment, the first upper interconnection 38 and the second upper interconnection 39 with different heights respectively are formed in the cell region S1 and the peripheral region S2 in self-alignment using a step generated by forming a pattern of the capacitor upper electrode layer 31. Hence, there is an advantage in that interconnections having different heights can be formed without newly adding a photolithographic process whose interconnection manufacturing cost is high. In detail, FIG. 5 of JP-A-10-223858 shows a method including processes as follows. An insulating film is formed over the entire surface to cover a stack capacitor after the stack capacitor is formed over a semiconductor substrate. Then, a step or level difference between a memory cell region and a peripheral circuit region is formed by etching the insulating film formed in the peripheral circuit part by lithography and dry etching method. In this method, two lithographic processes are necessary for a process for etching the insulating film formed in the peripheral circuit part in addition to a process of processing an upper electrode layer of the stack capacitor. On the other hand, in the method of manufacturing the semiconductor device of the present embodiment, the first upper interconnection 38 and the second upper interconnection 39 whose heights are different in self-alignment can be formed in the cell region S1 and the peripheral region S2 according to only one lithographic process used for processing the capacitor upper electrode layer 31. Accordingly, the method of manufacturing the semiconductor device of the present embodiment can reduce the interconnection capacity of the memory cell region and reduce the interconnection resistance of the peripheral circuit region while suppressing an increase in production cost by reducing the number of manufacturing processes.

In the method of manufacturing the semiconductor device of the present embodiment, the buried bit line 4 of this embodiment is formed to include an impurity-doped silicon material in order to provide excellent heat treatment resistance and oxidation resistance. There is a characteristic that such an impurity-doped silicon film has high interconnection resistance. Since the first upper interconnection 38 and the second upper interconnection 39 are formed by a final process, a low-temperature process can be used and a Cu interconnection having small interconnection resistance can be used.

The present invention is effective in a semiconductor device, which forms an interconnection requiring high density and an interconnection through which a high current flows, particularly, in DRAM.

### Second Embodiment

<Semiconductor Device>

FIG. 17 is a schematic cross-sectional view showing an example of a semiconductor device according to the second embodiment of the present invention. The semiconductor device according to the second embodiment is different from the above-described semiconductor device of the first embodiment as follows. Arrangements of the fifth interlayer insulating film over the fourth interlayer insulating film 14 and the capacitor upper electrode layer 31, the first upper interconnection 38, the second upper interconnection 39, and the second contact plug 35 are different, and other configurations are identical (that is, the configurations up to FIG. 4 are identical). Since the cell transistor Tr1 and the peripheral transistor Tr2 are the same as those of the first embodiment, illustration thereof is omitted in FIG. 17. In the following descriptions, the same components as those of the first embodiment described above are denoted by the same reference numerals, and descriptions thereof are omitted.

First, a cell region S1 of the semiconductor device of this embodiment will be described. As shown in FIG. 17, the cell region S1 of the semiconductor device of this embodiment schematically includes the following elements. A capacitor element 10 is connected to a cell transistor Tr1 via a cell contact plug 8 and a capacitor contact plug 9. A capacitor upper electrode layer 31 is formed over the capacitor element 10. A first upper interconnection 38B is formed over the capacitor upper electrode layer 31 via a fifth interlayer insulating film A51.

The fifth interlayer insulating layer A51 formed of an insulating film such as a silicon oxide film is formed to cover the surface and the side surface of the capacitor upper electrode layer 31. A fifth interlayer insulating film B52 and a fifth interlayer insulating film C53 are sequentially laminated and formed over the fifth interlayer insulating layer A51. As the fifth interlayer insulating film B52, the same material as the fifth interlayer insulating film C34 of the above-described first embodiment may be used. As the fifth interlayer insulating film C53, an insulating film such as a silicon oxide film may be used.

The first upper interconnection 38B is formed over the fifth interlayer insulating film A51 through the fifth interlayer insulating film B52 and the fifth interlayer insulating film C53. As the first upper interconnection 38B, the same material as that of the first upper interconnection 38 of the above-described first embodiment may be used. The first upper interconnection 38B extends in the X direction and is arranged at the same pitch as the buried bit line 4 in the Y direction.

Next, a peripheral region S2 of the semiconductor device of this embodiment will be described. As shown in FIG. 17, the peripheral region S2 of the semiconductor device of this embodiment includes a lower interconnection 24 and a second upper interconnection 39B. The lower interconnection 24 is connected to a peripheral transistor Tr2 via a first contact plug 23. The second upper interconnection 39B is connected to the lower interconnection 24. Further, the second upper interconnection 39B is formed to have a thickness that is greater (a height that is higher) than that of the first upper interconnection 38B in a vertical direction.

In the peripheral region S2, as in the above-described first embodiment, the fourth interlayer insulating film 14 and the fifth interlayer insulating film A51 are sequentially laminated over the third interlayer insulating film 13. The third interlayer insulating film 13 is formed to cover the lower interconnection 24. The second contact plug 35B is formed to be connected to the lower interconnection 24 through the third interlayer insulating film 13, the fourth interlayer insulating film 14, and the fifth interlayer insulating film A51. The second contact plug 35B is formed to include the same material as the second contact plug 35 of the above-described first embodiment.

The fifth interlayer insulating film B52 and the fifth interlayer insulating film C53 are sequentially laminated and formed over the fifth interlayer insulating film A51. The second upper interconnection 39B is formed over the fifth interlayer insulating film A51 and the second contact plug 35B to penetrate the fifth interlayer insulating film B52 and the fifth interlayer insulating film C53. The second upper interconnection 39B is formed to include the same material as the second upper interconnection 39 of the above-described first embodiment.

In this embodiment as shown in FIG. 17, the surface of the second contact plug 35B is consistent with that of the fifth interlayer insulating film A51. The surface of the second contact plug 35B is in contact with the second upper interconnection 39B, but the side surface of the second contact plug 35B has a structure that is not in contact with the second upper interconnection 39B.

In the semiconductor device of this embodiment like the above-described first embodiment, the capacitor upper electrode layer 31 is formed to cover the entire cell region S1, and is not formed in the peripheral region S2. Thus, as shown in FIG. 17, the height of the surface of the fifth interlayer insulating film A51 of the peripheral region S2 is lower than that of the fifth interlayer insulating film A51 of the cell region S1. Additionally, a step is formed by the fifth interlayer insulating film A51. The step is positioned around the boundary between the cell region S1 and the peripheral region S2. By providing the above-described step, the thickness of the first upper interconnection 38B can be thin and the thickness of the second upper interconnection 39B can be thick.

In the above-described first embodiment, the second contact plug 35 within the second upper interconnection trench 37b has a projection structure. In this structure, since a contact area of the second contact plug 35 and the second upper interconnection 39 is increased, there is an advantageous effect in that contact resistance is reduced. However, on the other hand, a gap between the second contact plug 35 and the second upper interconnection trench 37b is small (a bottom portion of the second upper interconnection trench 37b has a doughnut shape). Hence, there is a problem in that the gap filling property of a Cu film is degraded. In this embodiment, the second contact plug 35B within the upper interconnection trench 37b does not adopt a projection structure, so that the gap filling property of the Cu film can be improved in addition to the advantageous effect of the first embodiment.

<Method of Manufacturing Semiconductor Device>

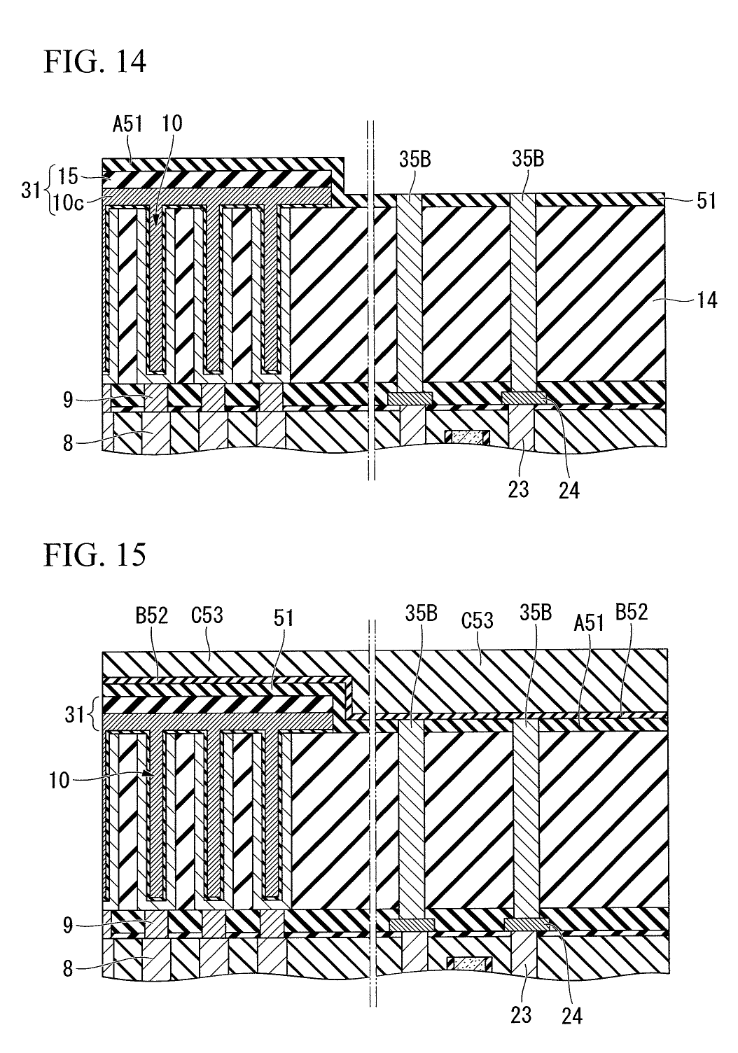

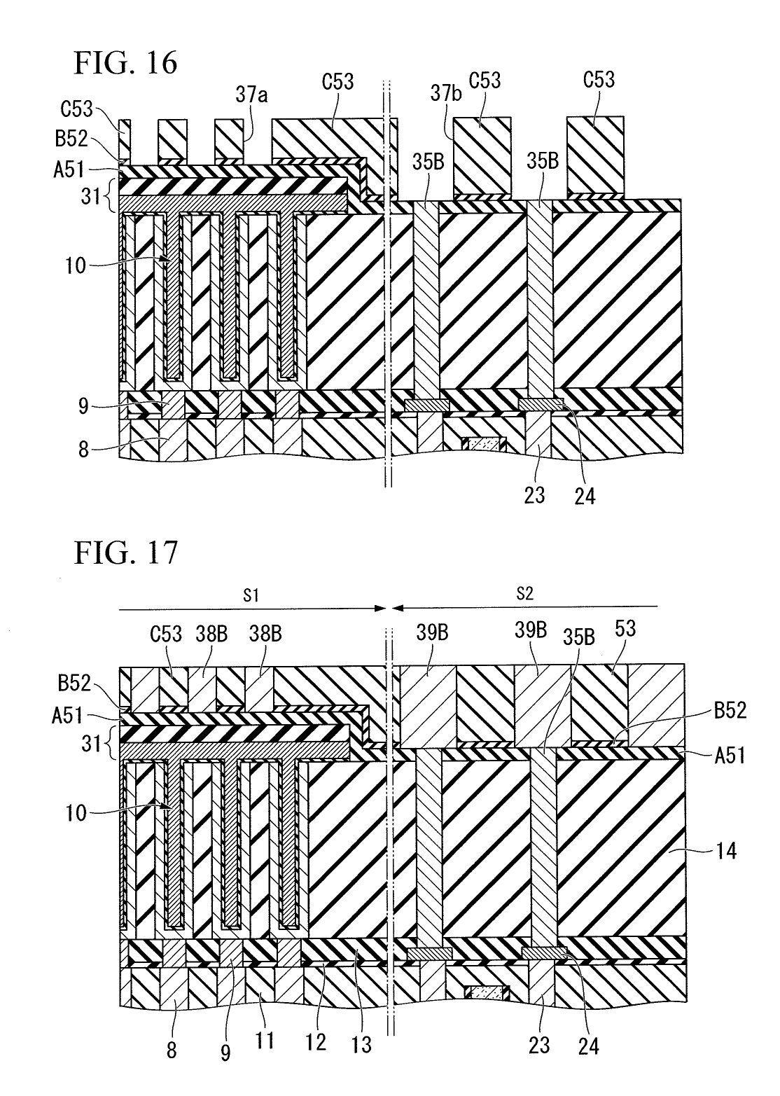

Next, the method of manufacturing the semiconductor device of this embodiment will be described with reference to FIGS. 14 to 17. In FIGS. 14 to 17, since the cell transistor Tr1 and the peripheral transistor Tr2 have the same configurations as those of the first embodiment, illustration thereof is omitted. In the following description, the same components as those of the above-described first embodiment are denoted by the same reference numerals, and a description thereof is omitted.

The method of manufacturing the semiconductor device of this embodiment schematically includes the following processes. A process (a first process) includes forming a cell transistor Tr1, which is a vertical MOS transistor, in a memory cell region (a cell region) S1, forming a peripheral transistor Tr2, which is a planar MOS transistor, in a peripheral circuit region (a peripheral region) S2, and forming a deep trench capacitor element 10 on the cell transistor Tr1 of the cell region S1. A process (a second process) includes forming a capacitor upper electrode layer 31 over the capacitor element 10 so as to cover the entire cell region S1. A process (a third process) includes forming a second contact plug 35B in the peripheral region S2. A process (a fourth process) includes forming a first upper interconnection 38B and a second upper interconnection 39B. The manufacturing method up to the second process (FIG. 4) of the above-described first embodiment is the same as the method of manufacturing the semiconductor device of this embodiment. Hereinafter, the third and fourth processes will be described in detail.

[Third Process] (Process of Forming Fifth Interlayer Insulating Film A51)

The fifth interlayer insulating film A51 is formed by forming an insulating film such as a silicon oxide film using a CVD method to cover the capacitor upper electrode layer 31 of a fourth interlayer insulating film 14 of the cell region S1 and the peripheral region S2 (a process of forming the second contract plug 35B).

In the peripheral region S2, a second contact hole is formed by a known method using a mask having a pattern of the second contact hole. The second contact hole reaches a lower interconnection 24 through the fifth interlayer insulating film A51, the fourth interlayer insulating film 14, and the third interlayer insulating film 13. Next, a second contact filling material fills the second contact hole. The second contact filling material may be formed of a laminated film which includes a TiN film and a W film to cover the fifth interlayer insulating film A51. Subsequently, the second contact plug 35B is formed by etch-back process (FIG. 14). This etch-back is performed so that an etching residue does not occur on the sidewall of the capacitor upper electrode layer 31.

“Fourth Process” (Process of Forming Fifth Interlayer Insulating Films B52 and C53)

The fifth interlayer insulating film B52 and the fifth interlayer insulating film C53 are formed by forming a silicon oxide film using a CVD method or the like to cover the fifth interlayer insulating film A51 (FIG. 15). Next, the fifth interlayer insulating film C53 is polished and planarized using a CMP method. The thickness of the fifth interlayer insulating film C53 is adjusted and set in accordance with the heights of the first upper interconnection 38B and the second upper interconnection 39B to be formed in a process to be described later.

(Process of Forming First Upper Interconnection 38B and Second Upper Interconnection 39B)

A trench portion is formed in the fifth interlayer insulating film C53 by etching the fifth interlayer insulating film C53 using the fifth interlayer insulating film B52 as an etching stopper film and using an upper interconnection trench mask. The upper interconnection trench mask has a shape in which portions to form the first upper interconnection 38B and the second upper interconnection 39B are opened. A cell-region upper interconnection trench 37a and a second upper interconnection trench 37b are formed by etching the fifth interlayer insulating film B52 to expose the surface of the second contact plug 35B. Here, the plan view of the upper interconnection trench mask corresponds to the upper interconnection pattern shown in FIG. 12, as in the semiconductor device of the first embodiment. A plurality of patterns of the first upper interconnection trenches 37a extend in the X direction and are arranged at the same pitch as the buried bit line 4 in the Y direction.

Next, within the cell-region upper interconnection trench 37a and the second upper interconnection trench 37b, and on the surface of the fifth interlayer insulating film C53, an underlying layer is formed to include Cu or the like as follows. A TiN film is formed as a barrier metal by a sputtering method. A seed film serving as a seed layer is formed by a sputtering method. A Cu film is formed thereon using a plating method. A Cu interconnection is used here, but a metal interconnection or the like using an Al film or a W film may be used. Thereafter, by polishing and removing the Cu film and the underlying layer using a CMP method, the surface of the fifth interlayer insulating film C53 is exposed and also the underlying layer and the Cu film are buried in the cell-region upper interconnection trench 37a and the second upper interconnection trench 37b. Thereby, the first upper interconnection 38B and the second upper interconnection 39B are formed and the second upper interconnection 39B is connected to the second contact plug 35B.

In the method of manufacturing the semiconductor device of this embodiment, the second upper interconnection 39B is configured to be formed on the surface of the second contact plug 35B. Thus, it is possible to prevent a decrease in gap between the second contact plug 35B and the cell-region upper interconnection trench 37b (a doughnut shape of the bottom portion of the cell-region upper interconnection trench 37b). Accordingly, it is possible to improve the gap filling property of the Cu film within the second upper interconnection trench 37b when the second upper interconnection 39B is formed in addition to the advantageous effect of the first embodiment.

### Third Embodiment

### Semiconductor Device

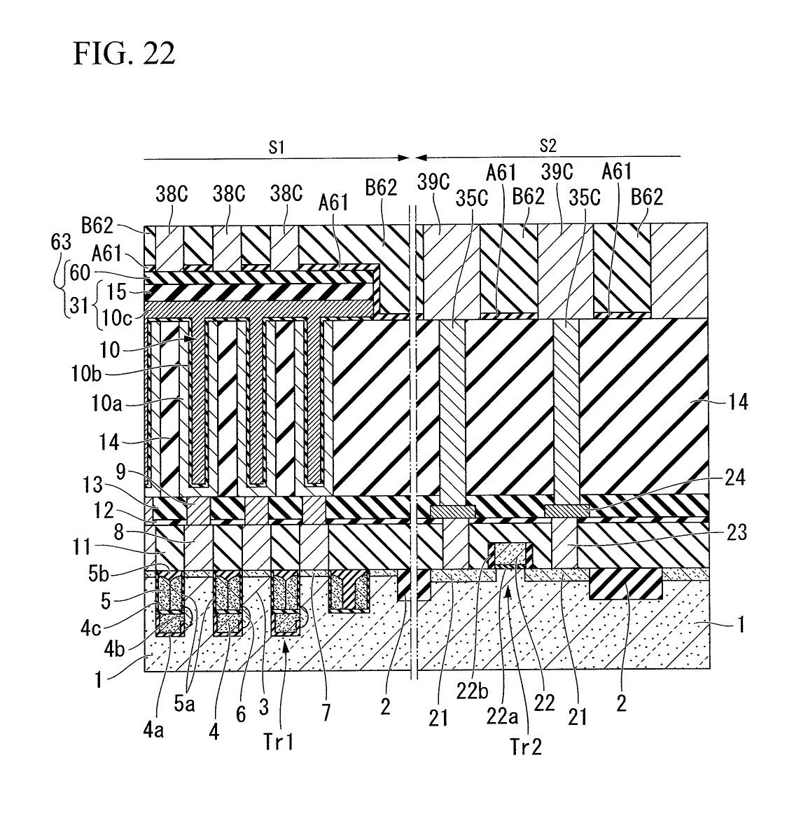

FIG. 22 is a schematic cross-sectional view showing an example of the semiconductor device according to the third embodiment of the present invention. The semiconductor device according to the third embodiment is different from the above-described semiconductor device of the first embodiment as follows. Arrangements of the fifth interlayer insulating film over the fourth interlayer insulating film 14 and the capacitor upper electrode layer 31, the first upper interconnection 38, the second upper interconnection 39, and the second contact plug 35 are different. A capacitor electrode cap film 60 is formed over the capacitor upper electrode layer 31. Other configurations are identical (that is, configurations up to FIG. 4 are identical). In the following description, the same components as those of the first embodiment described above are denoted by the same reference numerals, and a description thereof is omitted.

First, a cell region S1 of the semiconductor device of this embodiment will be described. As shown in FIG. 22, the cell region S1 of the semiconductor device of this embodiment schematically includes the following elements. A capacitor element 10 is connected to a cell transistor Tr1 via a cell contact plug 8 and a capacitor contact plug 9. A capacitor upper electrode layer 31 is formed over the capacitor element 10, the capacitor electrode cap film 60 is formed over the capacitor upper electrode layer 31. A first upper interconnection 38C is formed over the capacitor electrode cap film 60.

The capacitor electrode cap film 60 is formed over the surface of the capacitor upper electrode layer 31 (the surface of a capacitor electrode protection film 15), for example, using a silicon nitride film. Like the capacitor upper electrode layer 31, the capacitor electrode cap film is formed to cover all of a plurality of memory cells formed in the cell region S1. In the following description, the capacitor electrode cap film 60 and the capacitor upper electrode layer 31 may be collectively referred to as a “capacitor upper layer 63.”

A fifth interlayer insulating layer A61 is formed of an insulating film such as a silicon oxide film to cover the surface of the capacitor electrode cap film 60 and the side surface of the capacitor electrode cap film 60. A fifth interlayer insulating film B62 is formed of an insulating film such as a silicon oxide film to cover the fifth interlayer insulating layer A61.

A first upper interconnection 38C is formed on the capacitor electrode cap film 60 through the fifth interlayer insulating film A61 and the fifth interlayer insulating film B62. As the first upper interconnection 38C, the same material as that of the first upper interconnection 38 of the above-described first embodiment may be used. The first upper interconnection 38C extends in the X direction and is arranged at the same pitch as the buried bit line 4 in the Y direction.

Next, a peripheral region S2 of the semiconductor device of this embodiment will be described. As shown in FIG. 22, the peripheral region S2 of the semiconductor device of this embodiment schematically includes the following elements. A lower interconnection 24 is connected to a peripheral transistor Tr2 via a first contact plug 23. A second upper interconnection 39C is connected to the lower interconnection 24 via a second contact plug 35C. Additionally, the second upper interconnection 39C is formed to have a thickness that is greater (a height that is higher) than that of the first upper interconnection 38C in the vertical direction.

In the peripheral region S2 as in the above-described first embodiment, a fourth interlayer insulating film 14 is formed over a third interlayer insulating film 13 formed to cover the lower interconnection 24. A second contact plug 35C is formed to be connected to the lower interconnection 24 through the third interlayer insulating film 13 and the fourth interlayer insulating film 14. The second contact plug 35C is formed of the same material as the second contact plug 35 of the above-described first embodiment.

The fifth interlayer insulating film A61 and the fifth interlayer insulating film B62 formed of insulating films such as silicon oxide films are sequentially laminated and formed over the fourth interlayer insulating film 14. The second upper interconnection 39C is formed over the fourth interlayer insulating film 14 and the second contact plug 35C to penetrate the fifth interlayer insulating film A61 and the fifth interlayer insulating film B62. The second upper interconnection 39C is formed of the same material as the second upper interconnection 39 of the above-described first embodiment.

In this embodiment as shown in FIG. 22, the surface of the second contact plug 35C is consistent with that of the fourth interlayer insulating film 14. The surface of the second contact plug 35C is in contact with the second upper interconnection 39C, but the side surface of the second contact plug 35C has a structure that is not in contact with the second upper interconnection 39C.

In the semiconductor device of this embodiment, the capacitor upper electrode layer 31 and the capacitor electrode cap film 60 are formed to cover the entire cell region S1, and are not formed in the peripheral region S2. Thus, as shown in FIG. 22, the height of the surface of the fifth interlayer insulating film A61 of the peripheral region S2 is lower than that of the fifth interlayer insulating film A61 of the cell region S1. A step formed by the fifth interlayer insulating film A61 is formed around a boundary between the cell region S1 and the peripheral region S2. By providing the above-described step, the thickness of the first upper interconnection 38C can be thin and the thickness of the second upper interconnection 39C can be thick.

In this embodiment, like the second embodiment, the second contact plug 35C within the upper interconnection trench 37b does not adopt a projection structure, so that the gap filling property of the Cu film can be improved in addition to the advantageous effect of the first embodiment. In this embodiment, a configuration in which the fifth interlayer insulating film A61 is formed beneath the fifth interlayer insulating film B62 has been illustrated, but the fifth interlayer insulating film A61 may be omitted.

<Method of Manufacturing Semiconductor Device>

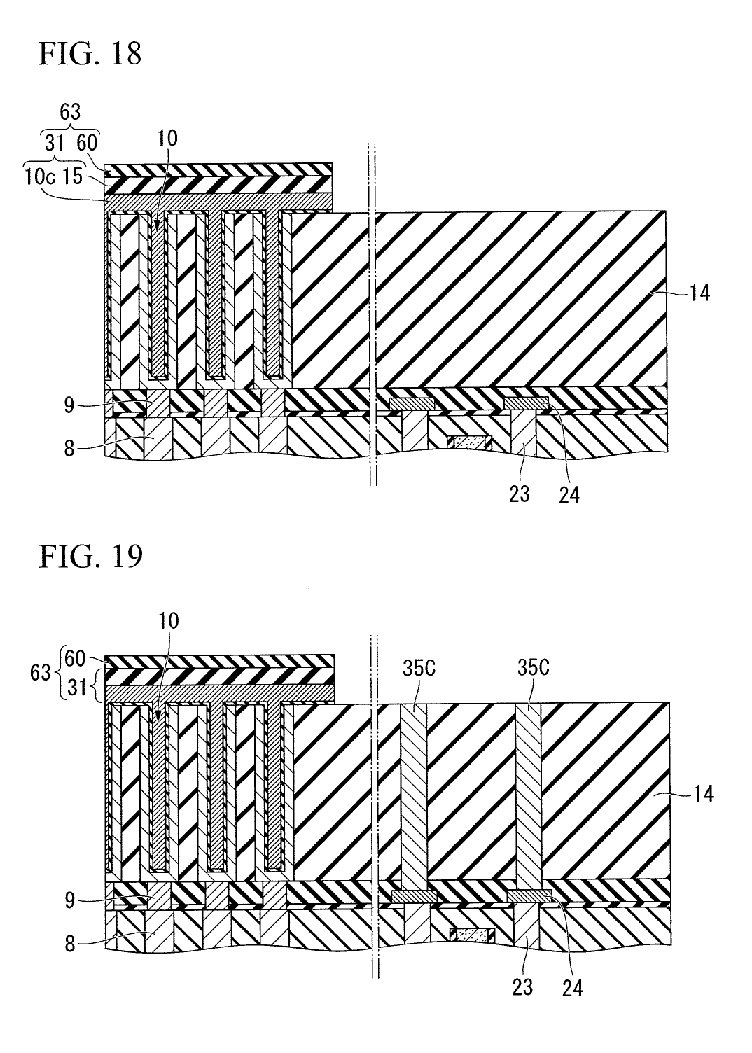

Next, the method of manufacturing the semiconductor device of this embodiment will be described with reference to FIGS. 18 to 22. In FIGS. 18 to 22, since the cell transistor Tr1 and the peripheral transistor Tr2 have the same configurations as those of the first embodiment, illustration thereof is omitted. In the following description, the same components as those of the above-described first embodiment are denoted by the same reference numerals, and a description thereof is omitted.

The method of manufacturing the semiconductor device of this embodiment schematically includes the following processes. A process (a first process) includes forming a cell transistor Tr1, which is a vertical MOS transistor, in a memory cell region (a cell region) S1, forming a peripheral transistor Tr2, which is a planar MOS transistor, in a peripheral circuit region (a peripheral region) S2, and forming a deep trench capacitor element 10 on the cell transistor Tr1 of the cell region S1. A process (a second process) includes forming a capacitor upper electrode layer 31 on the capacitor element 10 so as to cover the entire cell region S1. A process (a third process) includes forming a second contact plug 35C in the peripheral region S2. A process (a fourth process) includes forming a first upper interconnection 38C and a second upper interconnection 39C. The manufacturing method up to the second process of forming the capacitor electrode protection film 15 (FIG. 1) in the above-described first embodiment is the same as the method of manufacturing the semiconductor device of this embodiment. Hereinafter, a process after the process of forming the capacitor electrode protection film 15 will be described in detail.

[Second Process] (Process of Forming Capacitor Upper Electrode Layer 31 and Capacitor Electrode Cap Film 60)

In the manufacturing method, as in the first embodiment as shown in FIG. 1, a capacitor electrode protection film 15 is formed and then a silicon nitride film is formed on the capacitor electrode protection film 15 by an LP-CVD (reduced pressure CVD) method or the like. Next, a photoresist pattern is formed to cover the entire cell region S1 by a lithography method. The silicon nitride film, the capacitor electrode protection film 15, and a capacitor upper electrode film 10c are sequentially etched using the photoresist pattern as a mask. A capacitor upper layer 63 including the capacitor electrode cap film 60 and the capacitor upper electrode layer 31 is formed (FIG. 18). Even in this embodiment like the first embodiment, the capacitor upper electrode layer 31 and the capacitor upper layer 63 are formed in a plate pattern, which covers all of the plurality of memory cells formed in the cell region S1.

[Third Process] (Process of Forming Second Contact Plug 35C)

In the peripheral region S2, a second contact hole, which reaches the lower interconnection 24 through the fourth interlayer insulating film 14 and the third interlayer insulating film 13, is opened by a general method using a mask having a pattern of the second contact hole. Next, a second contact filling material fills the second contact hole and a laminated film of a TiN film and a W film are formed to cover the fourth interlayer insulating film 14. Subsequently, a second contact plug 35B is formed by filling the second contact filling material in the second contact hole and an etch-backed (FIG. 19). This etch-back is performed so that an etching residue does not occur on the sidewall of the capacitor upper electrode layer 31.

[Fourth Process] (Process of Forming Fifth Interlayer Insulating Films A61 and B62)

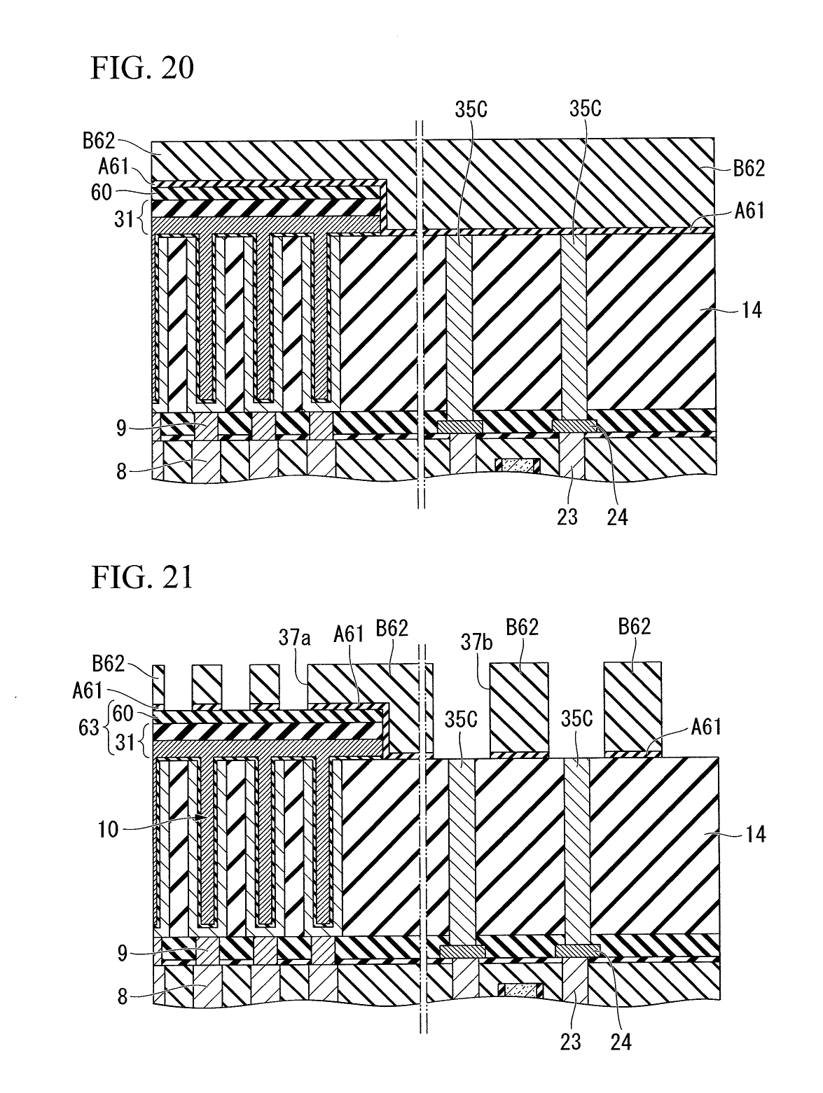

The fifth interlayer insulating film A61 and the fifth interlayer insulating film B62 are formed of a silicon oxide film using a CVD method to cover the surface of the capacitor electrode cap film 60 and the sidewall of the capacitor electrode layer 63 (FIG. 20). Next, the fifth interlayer insulating film B62 is polished and planarized using a CMP method. The thickness of the fifth interlayer insulating film B62 is adjusted and set in accordance with the heights of the first upper interconnection 38C and the second upper interconnection 39C to be formed in a process to be described later.

(Process of Forming First Upper Interconnection 38C and Second Upper Interconnection 39C)

A trench portion is formed in the fifth interlayer insulating film B62 by etching the fifth interlayer insulating film B62 using the fifth interlayer insulating film A61 as an etching stopper film and using an upper interconnection trench mask. The upper interconnection trench mask has a shape in which portions to form the first upper interconnection 38C and the second upper interconnection 39C are opened. The cell-region upper interconnection trench 37a and the second upper interconnection trench 37b are formed by etching the fifth interlayer insulating film A61 to expose the surface of the second contact plug 35C (FIG. 21). Here, the plan view of the upper interconnection trench mask corresponds to the upper interconnection pattern shown in FIG. 12, as in the semiconductor device of the first embodiment. A plurality of patterns of the first upper interconnection trenches 37a extend in the X direction and are arranged at the same pitch as the buried bit line 4 in the Y direction.

Next, within the cell-region upper interconnection trench 37a and the second upper interconnection trench 37b, and on the surface of the fifth interlayer insulating film B62, an underlying layer is formed to include Cu or the like as follows. A TiN film is formed as a barrier metal by a sputtering method. A seed film serving as a seed layer is formed by a sputtering method. A Cu film is formed thereon using a plating method. A Cu interconnection is used here, but a metal interconnection or the like using an Al film or a W film may be used. Thereafter, by polishing and removing the Cu film and the underlying layer using a CMP method, the surface of the fifth interlayer insulating film B62 is exposed. Also, the underlying layer and the Cu film are buried in the cell-region upper interconnection trench 37a and the second upper interconnection trench 37b. Thereby, the first upper interconnection 38C and the second upper interconnection 39C are formed and the second upper interconnection 39C is connected to the second contact plug 35C.

In the method of manufacturing the semiconductor device of this embodiment, the second upper interconnection 39C is configured to be formed on the surface of the second contact plug 35C. Thus, it is possible to prevent a decrease in gap between the second contact plug 35C and the cell-region upper interconnection trench 37b, which is a doughnut shape of the bottom portion of the cell-region upper interconnection trench 37b. Accordingly, it is possible to improve the gap filling property of the Cu film within the second upper interconnection trench 37b when the second upper interconnection 39C is formed in addition to the advantageous effect of the first embodiment.

In the method of manufacturing the semiconductor device of this embodiment, it is possible to prevent the exposure of the capacitor upper electrode 10c when the cell-region upper interconnection trench 37a is etched by forming the capacitor electrode cap film 60 over the capacitor upper electrode protection film 15. A configuration in which the fifth interlayer insulating film A61 is formed beneath the fifth interlayer insulating film B62 has been illustrated in this embodiment, but the present invention is not limited thereto. If there is no problem in control of the depth of etching of the second upper interconnection trench 37b, the fifth interlayer insulating film A61 may be omitted.

### Modifications to the Embodiments

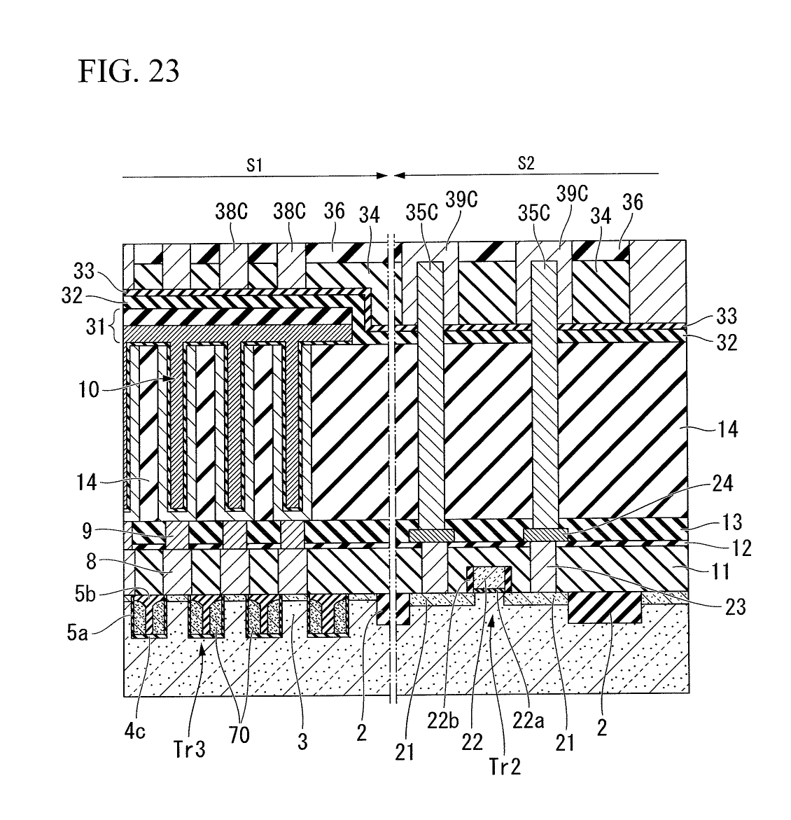

An example to which the formation of a main bit line in a hierarchical bit line structure and the formation of an interconnection in the peripheral region S2 are applied has been described in the first to third embodiments, but the present invention is not limited thereto. The present invention is applicable to form interconnections having different heights. Specifically, for example, the present invention is applicable to a shunt wiring structure which includes a low-resistance main word line in one-to-one correspondence with word lines of the memory cell region as shown in FIG. 23.

In the semiconductor device shown in FIG. 23, a planar MOS transistor is provided in the peripheral region S2 as in the first to third embodiments, and a trench gate type MOS transistor is provided in the cell region S1. Except for a cell transistor Tr3, the other components are the same in the semiconductor devices of the first to third embodiments. In FIG. 23, the same components as those of the first to third embodiments are denoted by the same reference numerals.

The semiconductor device shown in FIG. 23 can be manufactured by substantially the same manufacturing method as that of the first embodiment, except that a general trench gate type MOS transistor is formed in the cell region S1 as the cell transistor Tr3. Hereinafter, only differences from the first embodiment will be described.

In a process of forming the first upper interconnection in the cell region and the second upper interconnection in the peripheral region S2 of the fourth process of the first embodiment using the method of manufacturing the semiconductor device of this embodiment, the mask pattern of a first upper interconnection trench has a pattern extending in the Y direction. Patterns arranged in one-to-one correspondence with word lines 70 formed in semiconductor pillars 10 are used. After the first upper interconnection trench and the second upper interconnection trench are formed using the patterns, the first upper interconnection and the second upper interconnection are formed by the same method as that of the first embodiment. Thereby, first upper interconnections are formed in one-to-one correspondence with word lines having patterns extending in the Y direction. From a demand for high integration of memory cells, the word lines are designed to have a width and an interval using dimensions close to a minimum processing size of a photolithographic technique. Also, the word lines are formed in a line and space pattern (hereinafter, referred to as an L/S pattern) shape. Thus, the first upper interconnection trench pattern is also arranged and formed in the L/S pattern shape using dimensions close to the minimum processing size of the photolithographic technique. The width of the cell-region upper interconnection is close to the minimum processing size as described above. Therefore, it is difficult to secure the step coverage of the barrier layer and the seed layer within the cell-region upper interconnection trench when the cell-region upper interconnection is formed. Additionally, an interconnection height is limited, as in the first embodiment.

In the foregoing embodiments, it is possible to form upper interconnections respectively having appropriate heights in the cell region S1 and the peripheral region S2 as follows. A structure is formed such that the upper interconnection having a low height (a thin thickness in the vertical direction) is formed in the memory cell region and the upper interconnection having a high height (a thick thickness in the vertical direction) is formed in the peripheral circuit region. Accordingly, the interconnection capacity of the memory cell region can be reduced. Also, the interconnection resistance of the peripheral circuit region can be reduced.

The foregoing embodiments are effective to semiconductor devices, which form an interconnection requiring high density and an interconnection through which a high current flows, particularly, in DRAM.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method for forming a semiconductor device, comprising:
forming a substrate structure having an insulating upper surface, the insulating upper surface having a step;
forming an insulating layer over the insulating upper surface, the insulating layer covering the step, the insulating layer comprising first and second portions which are bounded by the step, the first portion being thinner than the second portion;
forming first and second grooves in the first and second portions, respectively, the first groove being shallower than the second groove; and
forming first and second conductive films which fill up the first and second grooves, respectively, the first conductive film being thinner than the second conductive film.

2. The method according to claim 1, further comprising:
forming a contact plug in the substrate structure,
wherein forming the second groove comprising:
exposing side and top of the contact plug.

3. The method according to claim 2, wherein forming the second conductive film comprises:
forming the second conductive film which covers the side and top of the contact plug.

4. The method according to claim 2, wherein the contact plug has a top which is substantially the same in level as an upper surface of the insulating layer.

5. The method according to claim 1, further comprising:
forming a contact plug in the substrate structure,
wherein forming the second groove comprising:
exposing a top of the contact plug.

6. The method according to claim 5, wherein forming the second conductive film comprises:
forming the second conductive film which covers the top of the contact plug with a material of the second conductive film.

7. The method according to claim 1, further comprising:
forming an etching stopper film on the insulating upper surface,
wherein forming the first and second grooves comprises:
carrying out an etching process using the etching stopper film.

8. The method according to claim 7, wherein the contact plug has a top which is substantially the same level as an upper surface of the etching stopper film.

9. A method for forming a semiconductor device, comprising:
forming a semiconductor substrate;
forming an interlayer insulating film over the semiconductor substrate;
selectively forming a layered structure over the interlayer insulating film, the layered structure having an edge;
forming a first insulating layer over the interlayer insulating film and the layered structure, the insulating layer covering the edge;
forming first and second grooves in the first insulating layer, the first groove being shallower than the second groove, the first groove being positioned over the layered structure, the second groove having a bottom level lower than the top of the layered structure; and
forming first and second conductive films which fill up the first and second grooves, respectively, the first conductive film being thinner than the second conductive film.

10. The method according to claim 9, further comprising:
forming a contact plug penetrating the interlayer insulating film,
wherein forming the second groove comprising:
exposing side and top of the contact plug.

11. The method according to claim 9, wherein forming the second conductive film comprises:
forming the second conductive film which covers the side and top of the contact plug.

12. The method according to claim 9, wherein the contact plug has a top which is substantially the same level as an upper surface of the first insulating layer.

13. The method according to claim 9, further comprising:
forming a contact plug in the substrate structure,
wherein forming the second groove comprising:
exposing a top of the contact plug.

14. The method according to claim 13, wherein forming the second conductive film comprises:
forming the second conductive film which covers the top of the contact plug with a material of the second conductive film.

15. The method according to claim 13, wherein the contact plug has a top which is substantially the same level as an upper surface of the interlayer insulating film.

16. The method according to claim 13, further comprising:
forming a third insulating layer on the layered structure, the third insulating layer being aligned to the layered structure.

17. The method according to claim 16, wherein the contact plug has a top which is substantially the same level as an upper surface of the interlayer insulating film.

18. The method according to claim 9, further comprising:
forming an etching stopper film over the interlayer insulating film and the layered structure,
wherein forming the first and second grooves comprises:
carrying out an etching process using the etching stopper film.

19. The method according to claim 18, wherein the contact plug has a top which is substantially the same level as an upper surface of the etching stopper film.

20. A method for forming a semiconductor device, comprising:
forming a semiconductor substrate having a memory cell region and a peripheral circuit region;
forming an interlayer insulating film over the semiconductor substrate;
forming a capacitor in the interlayer insulating film in the memory cell region;
forming an insulating layer over the capacitor in the memory cell region and the first interlayer insulating film in the peripheral circuit region;
forming first and second grooves in the insulating layer in the memory cell region and the peripheral circuit region, respectively, the first groove being positioned over the capacitor, the first groove being shallower than the second groove; and
forming first and second conductive films which fill up the first and second grooves, respectively, the first conductive film being thinner than the second conductive film.
